(19) United States
(12) Patent Application Publication
(10) Pub. No.: US 2023/0092256 A1
(43) Pub. Date: Mar. 23, 2023

(54) MARK, TEMPLATE, AND SEMICONDCTOR DEVICE MANUFACTURING METHOD

(71) Applicant: Kioxia Corporation, Tokyo (JP)

(72) Inventors: Sachiko Kobayashi, Ota Tokyo (JP); Kazuya Fukuhara, Yokkaichi Mie (JP); Katsuyoshi KODERA, Yokkaichi Mie (JP); Jun Watanabe, Fujisawa Kanagawa (JP); Koki Ueha, Yokkaichi Mie (JP)

(73) Assignee: Kioxia Corporation, Tokyo (JP)

(21) Appl. No.: 17/654,771

(22) Filed: Mar. 14, 2022

(30) Foreign Application Priority Data
Sep. 17, 2021 (JP) 2021-152441

(51) Int. Cl. G03F 9/00; H01L 21/66

(52) U.S. Cl. CPC G03F 9/7076; G03F 9/7088; G03F 9/7084; H01L 22/20; G03F 9/7042

(57) ABSTRACT

According to one embodiment, a mark is a mark arranged on a substrate and including a line-and-space pattern having a substantially constant pitch on the substrate, the mark including: a first mark in which the line-and-space pattern extends in a direction at an angle that is less than 90° or greater than 90° with respect to the first direction, the first mark including a pair of first patterns arranged at a distance in a first direction along the substrate or a first periodic pattern having a period in the first direction; and a second mark in which the line-and-space pattern extends in a direction at an angle that is less than 90° or greater than 90° with respect to the second direction, the second mark including a pair of second patterns provided in correspondence with the pair of first patterns and arranged at a distance in a second direction along the substrate and intersecting the first direction or a second periodic pattern provided in correspondence with the first periodic pattern and having a period in the second direction.

### CROSS-REFERENCE TO RELATED APPLICATIONS

This application is based upon and claims the benefit of priority from Japanese Patent Application No. 2021-152441, filed on Sep. 17, 2021; the entire contents of which are incorporated herein by reference.

### FIELD

Embodiments described herein relate generally to a mark, a template, and a semiconductor device manufacturing method.

### BACKGROUND

Methods for forming minute patterns in semiconductor device manufacturing processes include an imprint method. In the imprint method, processes such as alignment between a substrate and a pattern to be transferred onto the substrate and overlay misalignment measurement are performed. These processes are performed by using marks provided on a template, for example. It is desired to improve the precision of the alignment and overlay misalignment measurement.

### BRIEF DESCRIPTION OF THE DRAWINGS

FIG. 1 is a diagram illustrating an example configuration of an imprint device according to a first embodiment;

FIGS. 2A to 2E are diagrams illustrating an example procedure of processes performed by the imprint device according to the first embodiment;

FIG. 3 is a schematic diagram illustrating an example configuration of a wafer according to the first embodiment;

FIG. 4 is a schematic diagram illustrating an example configuration of a template according to the first embodiment;

FIGS. 5A to 5C are plan views illustrating an example configuration of marks provided to the template according to the first embodiment;

FIGS. 6A to 6D are diagrams illustrating an example procedure of a method for designing a mark provided to the template according to the first embodiment;

FIGS. 7Aa to 7Bc are diagrams illustrating an example procedure for forming a mark provided to the template according to the first embodiment;

FIGS. 8Aa to 8Bc are diagrams illustrating an example procedure for forming a mark provided to the template according to the first embodiment;

FIGS. 9A to 9C are plan views of a mark provided to a template according to a comparative example;

FIGS. 10A to 10C are plan views illustrating an example configuration of marks provided to a template according to a first variation of the first embodiment;

FIGS. 11A to 11C are plan views illustrating an example configuration of marks provided to a template according to a second variation of the first embodiment;

FIGS. 12A to 12C are plan views illustrating an example configuration of marks provided to a template according to a third variation of the first embodiment;

FIG. 13 is a sectional view along a measurement direction of marks respectively provided to a template and a wafer according to a second embodiment, illustrating a schematic configuration of the marks;

FIG. 14 is a schematic diagram illustrating an example of moire patterns generated by marks according to the second embodiment;

FIG. 15 is a plan view illustrating an example configuration of a mark provided to the template according to the second embodiment;

FIG. 16 is a plan view illustrating an example configuration of another mark provided to the template according to the second embodiment;

FIG. 17 is a plan view illustrating an example configuration of a mark provided to the wafer according to the second embodiment; and

FIG. 18 is a plan view illustrating an example configuration of another mark provided to the wafer according to the second embodiment.

### DETAILED DESCRIPTION

A mark of an embodiment is a mark arranged on a substrate and including a line-and-space pattern having a substantially constant pitch on the substrate, the mark including: a first mark in which the line-and-space pattern extends in a direction at an angle that is less than 90° or greater than 90° with respect to the first direction, the first mark including a pair of first patterns arranged at a distance in a first direction along the substrate or a first periodic pattern having a period in the first direction; and a second mark in which the line-and-space pattern extends in a direction at an angle that is less than 90° or greater than 90° with respect to the second direction, the second mark including a pair of second patterns provided in correspondence with the pair of first patterns and arranged at a distance in a second direction along the substrate and intersecting the first direction or a second periodic pattern provided in correspondence with the first periodic pattern and having a period in the second direction.

The present invention will be described in detail below with reference to the drawings. Note that the present invention is not limited by the following embodiments. In addition, components in the following embodiments include those that can be easily assumed by those skilled in the art or that are substantially identical.

### First Embodiment

A first embodiment will be described in detail below with reference to the drawings.

(Example Configuration of Imprint Device)

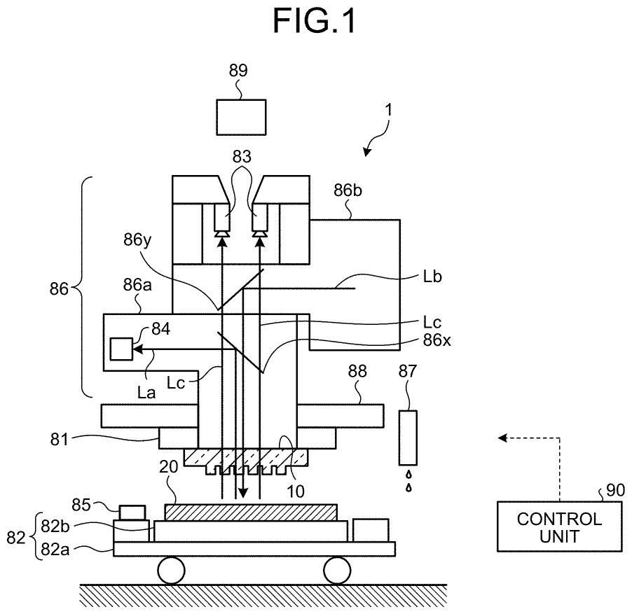

FIG. 1 is a diagram illustrating an example configuration of an imprint device 1 according to the first embodiment. As illustrated in FIG. 1, the imprint device 1 includes a template stage 81, a wafer stage 82, an alignment scope 83, a spread scope 84, a reference mark 85, an alignment unit 86, a liquid drop device 87, a stage base 88, a light source 89, and a control unit 90.

In addition, a template 10 for transferring a pattern onto a resist on a wafer 20 is installed on the imprint device 1. The template 10 is made of a transparent material such as quartz, and is arranged such that a transfer pattern faces the wafer stage 82, on which the wafer 20 is carried.

The wafer stage 82 includes a wafer chuck 82b and a main body 82a. The wafer chuck 82b fixes the wafer 20 at a predetermined position on the main body 82a. The reference mark 85 is provided on the wafer stage 82. The reference mark 85 is used for alignment in loading the wafer 20 on the wafer stage 82.

The wafer stage 82 carries the wafer 20 and moves in a plane (horizontal plane) parallel to the carried wafer 20. The wafer stage 82 moves the wafer 20 toward a position below the liquid drop device 87 for dropping a resist onto the wafer 20 and moves the wafer 20 toward a position below the template 10 for performing a process of transfer onto the wafer 20.

The stage base 88 supports the template 10 by means of the template stage 81 and moves the template 10 in the up-down direction (vertical direction) to push the transfer pattern of the template 10 against the resist on the wafer 20.

The alignment unit 86 is provided on the stage base 88. The alignment unit 86 performs detection of the position of the wafer 20 and detection of the position of the template 10 based on alignment marks respectively provided to the wafer 20 and the template 10 or the like.

The alignment unit 86 includes a detection system 86a and an illumination system 86b. The illumination system 86b irradiates the wafer 20 and the template 10 with light. The detection system 86a detects images of the alignment marks on the wafer 20 and the template 10 by means of the alignment scope 83 and performs alignment between the wafer 20 and the template 10 based on a detection result. In addition, the detection system 86a detects, by means of the spread scope 84, whether the transfer pattern of the template 10 is filled with the resist of the wafer 20 when the template 10 is pushed against the resist.

The detection system 86a and the illumination system 86b each include mirrors 86x and 86y, such as dichroic mirrors, which serve as an image formation unit. The mirrors 86x and 86y form images from the wafer 20 and the template 10 by means of light from the illumination system 86b.

Specifically, light Lb from the illumination system 86b is reflected by the mirror 86y in the downward direction, in which the template 10 and the wafer 20 are arranged. Light La from the wafer 20 and the template 10 is reflected by the mirror 86x toward the detection system 86a and travels to the spread scope 84. Light Lc from the wafer 20 and the template 10 passes through the mirrors 86x and 86y and travels to the alignment scope 83 above.

The liquid drop device 87 is a device for dropping a resist onto the wafer 20 in an inkjet manner. An inkjet head provided to the liquid drop device 87 has a plurality of minute holes for jetting resist droplets and drops resist droplets onto the wafer 20.

Thus, the imprint device 1 of the first embodiment is configured to drop the resist onto the wafer 20. However, the entire surface of the wafer 20 may be coated with the resist by a spin coating method.

The light source 89 is a device for radiating light, such as ultraviolet light, capable of curing the resist and is provided above the stage base 88. The light source 89 radiates light through the template 10 with the template 10 being pushed against the resist. Note that the light radiated by the light source 89 may be infrared light, visible light, electromagnetic light, or the like instead of ultraviolet light as long as it is capable of curing the resist.

The control unit 90 is an information processing device for performing various processes for controlling the imprint device 1. The control unit 90 includes a computer including, for example, a central processing unit (CPU), a read only memory (ROM), a random access memory (RAM), and the like and performing predetermined arithmetic processes and control processes according to a program.

The control unit 90 controls the template stage 81, the wafer stage 82, the liquid drop device 87, the stage base 88, the light source 89, and the like based on observation images acquired by the alignment scope 83, the spread scope 84, and the like.

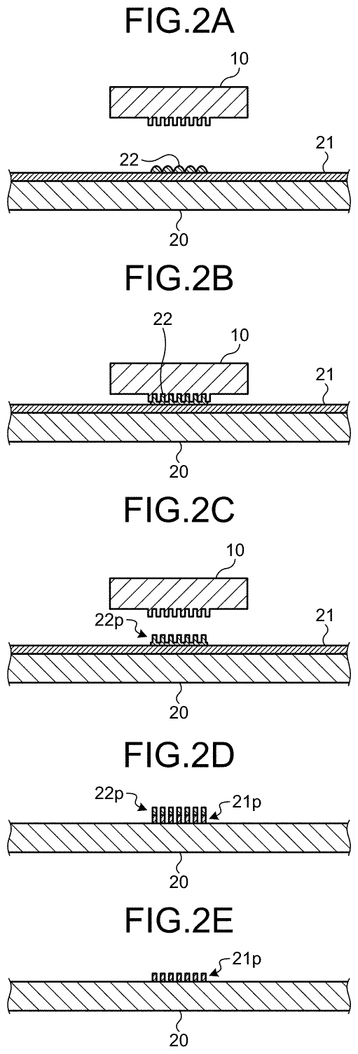

Processes performed using the imprint device 1 will now be briefly described with reference to FIGS. 2A to 2E. FIGS. 2A to 2E are diagrams illustrating an example procedure of processes performed by the imprint device 1 according to the first embodiment.

First, the wafer 20 on which a film to be processed 21 is formed is carried on the wafer stage 82. Then, the wafer stage 82 is moved to a position below the liquid drop device 87, and droplets of a resist 22 are dropped from the liquid drop device 87 onto the film to be processed 21. However, as described above, the entire surface of the wafer 20 may be coated with the resist 22 by a spin coating method.

As illustrated in FIG. 2A, the wafer stage 82 is moved to below the template 10, and the wafer 20 on which the resist 22 is dropped onto the film to be processed 21 is opposed to the surface of the template 10 on which the transfer pattern is formed.

As illustrated in FIG. 2B, the template stage 81 is moved downward, and the transfer pattern of the template 10 is pushed against the resist 22 while performing alignment by the alignment unit 86.

When it is detected by the spread scope 84 that asperities of the transfer pattern of the template 10 is filled with the resist, the resist 22 is irradiated with light from the light source 89 of the imprint device 1 to cure the resist 22 with the template 10 being pushed against it. Thus, the transfer pattern of the template 10 is transferred to the resist 22.

As illustrated in FIG. 2C, the template 10 is released. Thus, a resist pattern 22p obtained by the transfer of the transfer pattern of the template 10 is formed on the film to be processed 21 of the wafer 20.

Thus, the imprint process of the imprint device 1 ends. Thereafter, the film to be processed 21 of the wafer 20 is processed by processes in FIGS. 2D and 2E.

As illustrated in FIG. 2D, the resist pattern 22p is used as a mask to process the film to be processed 21 and form a film to be processed pattern 21p.

As illustrated in FIG. 2E, the resist pattern 22p is stripped by asking or the like.

Thereafter, a plurality of further steps will be performed to manufacture a semiconductor device.

(Example Configuration of Wafer and Template)

In the processes of the imprint device 1 described above, alignment between the wafer 20 and the template 10 is performed by using alignment marks provided to the wafer 20 and the template 10.

In addition, after the processes of the imprint device 1, measurement of the overlay misalignment amount of the pattern transferred to the resist 22 with respect to existing structures on the wafer 20 is performed. The overlay misalignment measurement is performed by using overlay marks provided to the wafer 20 and overlay marks transferred from the template 10 to the resist.

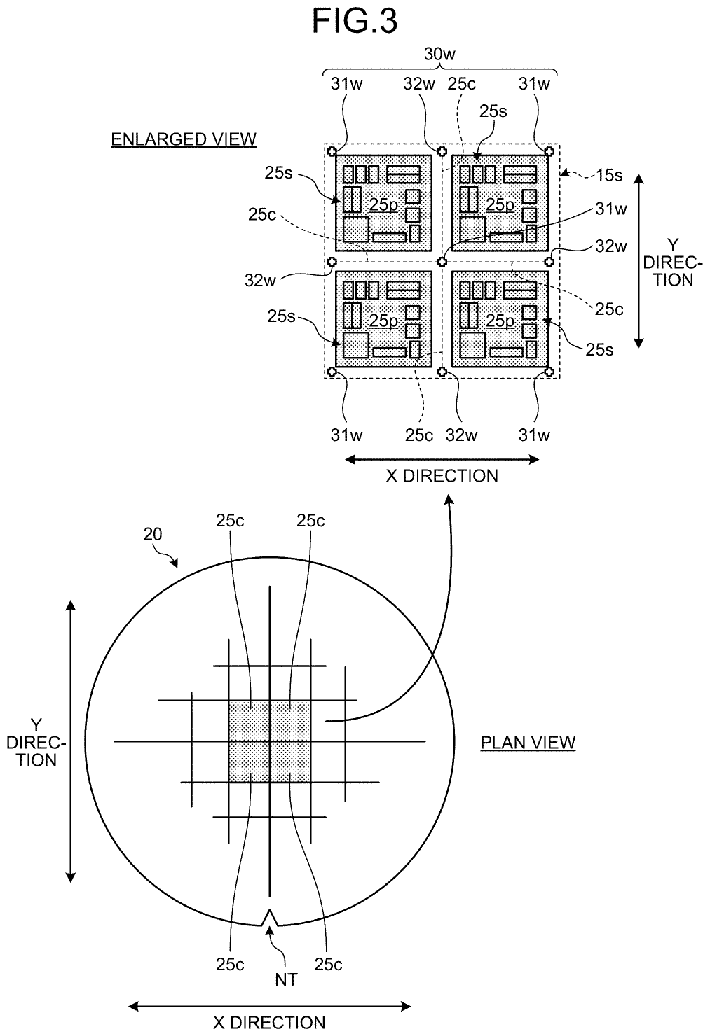

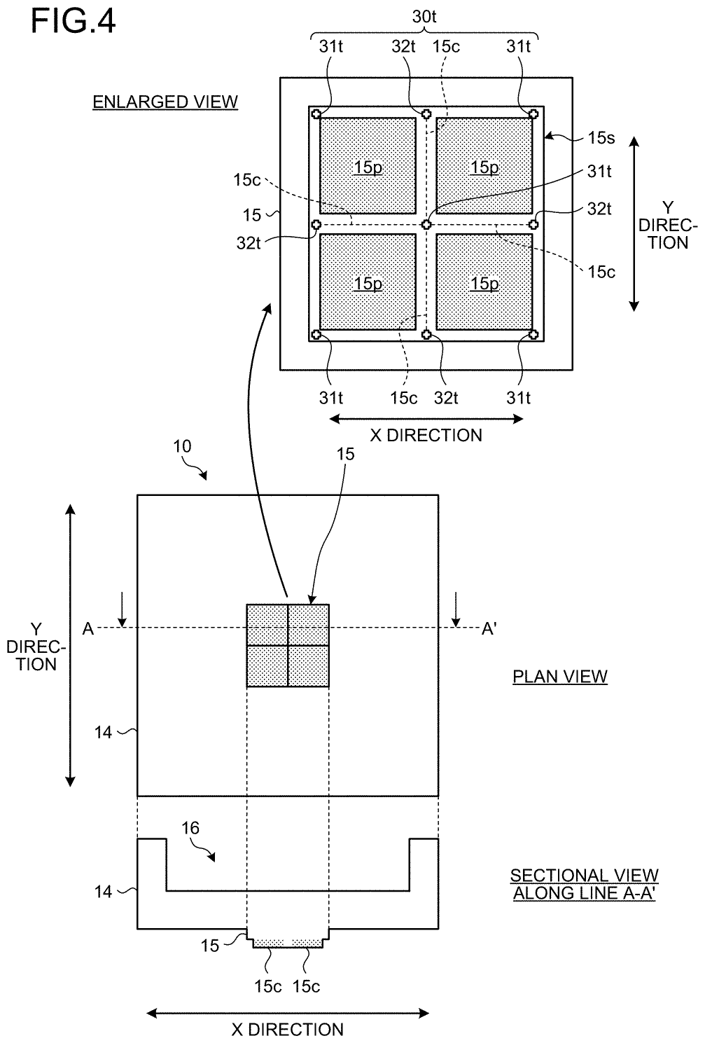

An example configuration of the wafer 20 and the template 10 of the first embodiment will be described below with reference to FIGS. 3 and 4.

FIG. 3 is a schematic diagram illustrating an example configuration of the wafer 20 according to the first embodiment. As described above, the wafer 20 at least includes the film to be processed 21. The wafer 20 may also include one or more underlying films (not illustrated) below the film to be processed 21.

As illustrated in FIG. 3, the wafer 20 includes a notch NT at one outer edge portion. The notch NT is a V-shaped notch provided for indicating the crystal orientation of the wafer 20. Seeing the wafer 20 is from above with the notch NT on the lower side, the left-right direction on the page is defined as an X direction as a first direction of the wafer 20, and the up-down direction is defined as a Y direction as a second direction.

The wafer 20 includes a plurality of chip regions 25c on its entire surface, for example. The chip regions 25c are regions to be cut out into chips in a late phase of the manufacturing process of the semiconductor device.

Some chip regions 25c adjacent to each other out of the plurality of chip regions 25c on the entire surface of the wafer 20 are included in one shot region 15s. The shot region 15s is a region in which the pattern is transferred to the resist 22 on the wafer 20 by one imprint process, that is, one stamping of the template 10.

Each chip region 25c includes a device portion 25p and a plurality of marks 30w outside the device portion 25p.

In the device portion 25p, various structures 25s such as grooves, holes, transistors, lines and vias, for example, have been formed by preceding processes on the wafer 20. The plurality of structures 25s are formed on the film to be processed 21, an underlying film of the film to be processed 21, or the like, for example.

The plurality of marks 30w are composed of asperities provided on any film including the film to be processed 21 on the wafer 20, for example. In addition, the plurality of marks 30w are arranged to have prescribed positional relationships with respective ones of the plurality of structures 25s formed in the device portion 25p. Typically, the plurality of marks 30w are arranged on the same film as the structures 25s having the prescribed positional relationships. However, the plurality of marks 30w may also be arranged on a different film than the structures 25s.

The plurality of marks 30w include a plurality of alignment marks 31w and a plurality of overlay marks 32w. The plurality of alignment marks 31w are used for alignment between the wafer 20 and the template 10 along with alignment marks of the template 10, which will be described later. The plurality of overlay marks 32w are used for overlay misalignment measurement along with overlay marks of the template 10, which will be described later.

Note that the configuration of the wafer 20 illustrated in FIG. 3 is merely an example and is not limiting. For example, although four chip regions 25c, four alignment marks 31w, and five overlay marks 32w are arranged in one shot region 15s in the example of FIG. 3, the number and arrangement of these are not limited to those in the example of FIG. 3.

FIG. 4 is a schematic diagram illustrating an example configuration of the template 10 according to the first embodiment. The template 10 of the first embodiment is made of a transparent material such as crystal or glass.

For the template 10 in FIG. 4 as well, an X direction and a Y direction are given in like manner with the wafer 20 for convenience. However, in the plan view and enlarged view of FIG. 4, the surface of the template 10 on the transfer pattern 15p side, that is, the side to be pushed against the wafer 20 is illustrated. Thus, it is to be noted that the left-right direction on the page in the X direction is reversed with respect to the case of the wafer 20.

As illustrated in FIG. 4, the template 10 includes a template substrate 14 that is rectangular in plan view, for example. The template substrate 14 is provided with a mesa portion 15 on its front surface and a countersink 16 in its back surface.

The mesa portion 15 is arranged at a central portion of the template substrate 14 and has a rectangular shape, for example. The mesa portion 15 includes a shot region 15s. The shot region 15s includes a plurality of pattern regions 15c in which minute transfer patterns 15p of a nano-order size, for example, are formed.

The transfer patterns 15p have a plurality of grooves, a plurality of dots, or other shapes and are asperity patterns to be transferred to the resist 22 of the wafer 20. After being transferred to the resist 22, these patterns become components of elements of the semiconductor device. A plurality of marks 30t are arranged outside the transfer patterns 15p of the shot region 15s.

The plurality of marks 30t are composed of asperities provided on the surface of the template 10. In addition, the plurality of marks 30t are arranged to have prescribed positional relationships with the transfer patterns 15p of the shot region 15s.

The plurality of marks 30t include a plurality of alignment marks 31t and a plurality of overlay marks 32t. The plurality of alignment marks 31t are used for alignment between the wafer 20 and the template 10 along with the alignment marks 31w of the wafer 20. The plurality of overlay marks 32t are used for overlay misalignment measurement along with the overlay marks 32w of the wafer 20.

More specifically, during the alignment between the wafer 20 and the template 10, the relative position between the wafer 20 and the template 10 is adjusted such that the respective alignment marks 31w and 31t are overlaid on each other as seen from above.

The alignment marks 31t of the template 10 are in prescribed positional relationships with the transfer patterns 15p on the template 10, and the alignment marks 31w of the wafer 20 are in prescribed positional relationships with the structures 25s on the wafer 20. It is thus possible to push the transfer patterns 15p of the template 10 at prescribed positions with respect to the predetermined structures 25s formed on the wafer 20.

In addition, in overlay misalignment measurement after the imprint process, the overlay misalignment amount between the overlay marks 32t and 32w is measured based on the degree of overlap between the overlay marks 32t transferred from the template 10 to the resist 22 and the existing overlay marks 32w on the wafer 20 as seen from above.

The overlay marks 32t of the template 10 are in prescribed positional relationships with the transfer patterns 15p on the template 10, and the overlay marks 32w of the wafer 20 are in prescribed positional relationships with the structures 25s on the wafer 20. It is thus possible to determine, from the overlay misalignment amount between the overlay marks 32t and 32w, the overlay misalignment amount of the patterns transferred to the resist 22 on the wafer 20 by stamping of the transfer patterns 15p of the template 10 with respect to the structures 25s.

Note that the configuration of the template 10 illustrated in FIG. 4 is merely an example and is not limiting. For example, although four pattern regions 15c, four alignment marks 31t, and five overlay marks 32t are arranged in one shot region 15s in the example of FIG. 4, the number and arrangement of these may vary as appropriate with their corresponding components of the wafer 20 described above.

In addition, hereinafter, when the marks 30t, alignment marks 31t, or overlay marks 32t arranged on the template 10 and the marks 30w, alignment marks 31w, or overlay marks 32w arranged on the wafer 20 are not distinguished, they are simply referred to as, for example, marks 30, alignment marks 31, or overlay marks 32, respectively.

(Example Configuration of Marks)

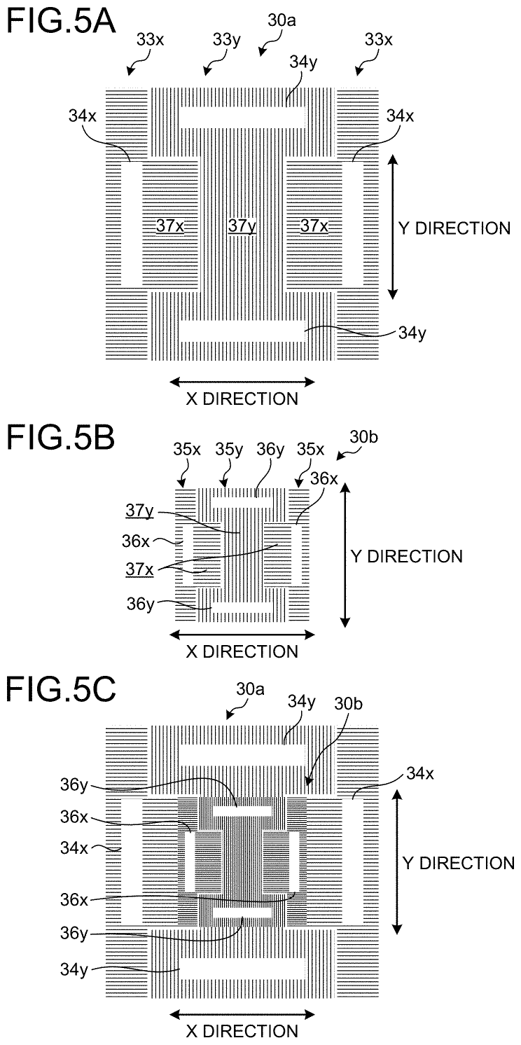

Next, an example configuration of marks 30t provided to the template 10 will be described with reference to FIGS. 5A to 5C. FIGS. 5A to 5C are plan views illustrating an example configuration of marks 30a and 30b provided to the template 10 according to the first embodiment.

Note that the marks 30t of the template 10 and the marks 30w of the wafer 20 have designs complementary to each other, and the designs of these marks 30t and 30w are interchangeable. FIGS. 5A and 5B illustrate these complementary marks 30a and 30b, and either of them may be arranged on the template 10, and they are not distinguished by the reference characters of the marks 30t and 30w.

That is, it is possible that the mark 30a in FIG. 5A is arranged on the template 10 and the mark 30b in FIG. 5B is arranged on the wafer 20. It is also possible that the mark 30b in FIG. 5B is arranged on the template 10 and the mark 30a in FIG. 5A is arranged on the wafer 20.

As described later, both of the marks 30a and 30b in FIGS. 5A and 5B are constituted by combining line-and-space (L/S) patterns 37x and 37y, in which included lines extend in respective different directions.

Since these L/S patterns 37x and 37y are formed by using the formation method described later, for example, free choice of the line widths, pitches, and the like of lines extending in the same direction may be restricted while the lines included in the L/S patterns 37x and 37y extend in respective different directions. That is, the line widths, pitches, and the like of the lines included in the L/S patterns 37x and 37y are fixed, for example.

Thus, in the following figures, L/S patterns arranged on the same template 10 or wafer 20 are consistently given like reference characters, such as the L/S patterns 37x and 37y, for example.

However, lines included in L/S patterns of a mark arranged on the template 10 and a mark arranged on the wafer 20 may have different line widths, pitches, or other configurations. In addition, the mark arranged on the wafer 20 may not be formed by combining L/S patterns and may be formed with a simple concave, convex, or another shape, for example.

In addition, the marks 30a and 30b illustrated in FIGS. 5A to 5C may be either alignment marks 31 or overlay marks 32. That is, the marks 30a and 30b illustrated in FIG. 5 are designed to be usable as either alignment marks 31 or overlay marks 32. The pair of marks 30a and 30b is referred to as a bar in bar mark, for example, due to its design.

In addition, the marks 30a and 30b illustrated in FIGS. 5A to 5C are shown as seen from above the wafer 20.

That is, the marks 30a and 30b illustrated in FIGS. 5A to 5C are shown as observed through the transparent template substrate 14 from above the template 10 with the transfer patterns 15p of the template 10 being pushed against the resist 22 on the wafer 20 during alignment.

Alternatively, the marks 30a and 30b illustrated in FIGS. 5A to 5C are shown as seen from above the wafer 20 when transferred from the template 10 to the resist on the wafer 20 or arranged on a predetermined film on the wafer 20 during overlay measurement.

Therefore, in FIGS. 5A to 5C, the left-right direction on the page in the X direction is consistent for both of the marks 30a and 30b.

As illustrated in FIG. 5A, the mark 30a includes an X mark 33x and a Y mark 33y. The X mark 33x is composed of a line-and-space (L/S) pattern 37x extending in a direction along the X direction. The Y mark 33y is composed of an L/S pattern 37y extending in a direction along the Y direction.

In the L/S pattern 37x, a plurality of lines have a substantially constant pitch, a plurality of spaces have a substantially constant pitch, and the pitch of the lines and the pitch of the spaces are substantially equal. That is, the lines and the spaces have substantially equal widths in the Y direction.

In the L/S pattern 37y, a plurality of lines have a substantially constant pitch, a plurality of spaces have a substantially constant pitch, and the pitch of the lines and the pitch of the spaces are substantially equal.

Further, the pitches of the lines and spaces in the L/S pattern 37x in the Y direction and the pitches of the lines and spaces in the L/S pattern 37y in the X direction are substantially equal respectively.

Having a substantially constant or equal pitch means that lines, spaces, or the L/S patterns 37x and 37y have a constant or equal pitch in an error range at the time of formation of the L/S patterns 37x and 37y, which will be described later, for example.

Note that, hereinafter, an L/S pattern in which the pitch between lines and the pitch between spaces are substantially constant and the pitch of lines and the pitch of spaces are substantially equal, such as the L/S patterns 37x and 37y, may be described as an L/S pattern having a substantially constant pitch.

In addition, the X mark 33x as a first mark includes bar patterns 34x as a pair of first patterns arranged at a distance in the X direction. The pair of bar patterns 34x are regions in which the L/S pattern 37x is not arranged in the region occupied by the X mark 33x, and are arrayed with each other in the X direction and extend in a direction along the Y direction.

In addition, the Y mark 33y as a second mark includes bar patterns 34y as a pair of second patterns arranged at a distance in the Y direction. The pair of bar patterns 34y are regions in which the L/S pattern 37y is not arranged in the region occupied by the Y mark 33y, and are arrayed with each other in the Y direction and extend in a direction along the X direction.

Note that, in the example of FIG. 5A, the L/S pattern 37x constituting the X mark 33x is separated in the X direction by the L/S pattern 37y constituting the Y mark 33y. Thus, the X mark 33x is divided into an L/S pattern 37x including one bar pattern 34x and an L/S pattern 37x including the other bar pattern 34x.

However, the configuration of the X mark 33x and the Y mark 33y is not limited to the example of FIG. 5A. For example, the L/S pattern 37x constituting the X mark 33x may separate the L/S pattern 37y constituting the Y mark 33y in the Y direction. Thus, the Y mark 33y may be divided into an L/S pattern 37y including one bar pattern 34y and an L/S pattern 37y including the other bar pattern 34y.

Besides, the X mark 33x and the Y mark 33y may have various configurations different than in FIG. 5A.

In addition, if the mark 30a is arranged on the wafer 20 instead of the template 10, the X mark 33x may not necessarily be composed of the L/S pattern 37x and the Y mark 33y may not necessarily be composed of the L/S pattern 37y as described above.

As illustrated in FIG. 5B, the mark 30b includes an X mark 35x and a Y mark 35y. The X mark 35x is composed of the L/S pattern 37x, for example, similar to the X mark 33x in FIG. 5A as described above. The Y mark 35y is composed of the L/S pattern 37y, for example, similar to the Y mark 33y in FIG. 5A as described above.

In addition, the X mark 35x as a first mark includes bar patterns 36x as a pair of first patterns arranged at a distance in the X direction. The pair of bar patterns 36x are regions in which the L/S pattern 37x is not arranged in the region occupied by the X mark 35x, and are arrayed with each other in the X direction and extend in a direction along the Y direction.

In addition, the Y mark 35y as a second mark includes bar patterns 36y as a pair of second patterns arranged at a distance in the Y direction. The pair of bar patterns 36y are regions in which the L/S pattern 37y is not arranged in the region occupied by the Y mark 35y, and are arrayed with each other in the Y direction and extend in a direction along the X direction.

However, the configuration of the X mark 35x and the Y mark 35y is not limited to the example of FIG. 5B, and they may have various configurations different than FIG. 5B, for example.

In addition, if the mark 30b is arranged on the wafer 20 instead of the template 10, the X mark 35x may not necessarily be composed of the L/S pattern 37x and the Y mark 35y may not necessarily be composed of the L/S pattern 37y as described above.

FIG. 5C illustrates how the marks 30a and 30b are overlaid.

To perform alignment using the marks 30a and 30b, the relative position between the template 10 and the wafer 20 is adjusted with the template 10 being pushed against the uncured resist 22 on the wafer 20, such that the X- and

Y-direction positions of the marks 30a and 30b arranged on the template 10 and the wafer 20 are overlaid as seen from above the template 10.

To align the X-direction positions of the template 10 and the wafer 20, the X-direction center position between the pair of bar patterns 34x of the X mark 33x of the mark 30a and the X-direction center position between the pair of bar patterns 36x of the X mark 35x of the mark 30b are matched. In this manner, the X-direction relative position between the structures 25s on the wafer 20 and the transfer patterns 15p of the template 10 is adjusted to a prescribed position.

To align the Y-direction positions of the template 10 and the wafer 20, the Y-direction center position between the pair of bar patterns 34y of the Y mark 33y of the mark 30a and the Y-direction center position between the pair of bar patterns 36y of the Y mark 35y of the mark 30b are matched. In this manner, the Y-direction relative position between the structures 25s on the wafer 20 and the transfer patterns 15p of the template 10 is adjusted to a prescribed position.

To perform overlay misalignment measurement using the marks 30a and 30b, the degree of overlap between the mark 30a or mark 30b transferred from the template 10 to the resist 22 on the wafer 20 and the mark 30b or mark 30a arranged on any film on the wafer 20 is observed.

To perform measurement of overlay misalignment between the marks 30a and 30b in the X direction, the distance between the X-direction center position between the pair of bar patterns 34x of the X mark 33x of the mark 30a and the X-direction center position between the pair of bar patterns 36x of the X mark 35x of the mark 30b is measured. The distance between these center positions is equal to the overlay misalignment amount in the X direction between the patterns transferred to the resist 22 by stamping of the transfer patterns 15p and the structures 25s on the wafer 20.

To perform measurement of overlay misalignment between the marks 30a and 30b in the Y direction, the distance between the Y-direction center position between the pair of bar patterns 34y of the Y mark 33y of the mark 30a and the Y-direction center position between the pair of bar patterns 36y of the Y mark 35y of the mark 30b is measured. The distance between these center positions is equal to the overlay misalignment amount in the Y direction between the patterns transferred to the resist 22 by stamping of the transfer patterns 15p and the structures 25s on the wafer 20.

Thus, in either case that the marks 30a and 30b are used as alignment marks 31 or overlay marks 32, the X marks 33x and 35x are used for misalignment amount measurement in the X direction. Likewise, the Y marks 33y and 35y are used for misalignment amount measurement in the Y direction. In alignment using the marks 30a and 30b, alignment in the X direction and the Y direction is performed based on the measured misalignment amount, and in overlay misalignment measurement using the marks 30a and 30b, the overlay misalignment amount in the X direction and the Y direction is identified based on the measured the misalignment amount.

Hereinafter, the X direction for the X marks 33x and 35x may be referred to as a measurement direction of the X marks 33x and 35x, and the Y direction for the Y marks 33y and 35y may be referred to as a measurement direction of the Y marks 33y and 35y.

Note that, in the example of FIG. 5C, the marks 30a and 30b are illustrated as being overlaid in an ideal state in which the misalignment amount is zero in both the X direction and the Y direction. However, in actual alignment, some degree of misalignment may occur in the relative position between the template 10 and the wafer 20 in both the X direction and the Y direction. Thus, after the imprint process, some degree of overlay misalignment may occur in both the X direction and the Y direction between the patterns transferred to the resist 22 and the structures 25s of the wafer 20.

In overlay misalignment measurement after the imprint process, if the overlay misalignment amount is within an acceptable range in both the X direction and the Y direction, processing on the film to be processed 21 of the wafer 20 is performed using the resist on which the patterns are transferred (the resist pattern 22p in FIG. 2C).

In overlay misalignment measurement after the imprint process, if the overlay misalignment amount in either the X direction or the Y direction is out of the acceptable range, the resist to which the patterns are transferred is stripped, and the imprint process is performed again.

(Method for Manufacturing Template)

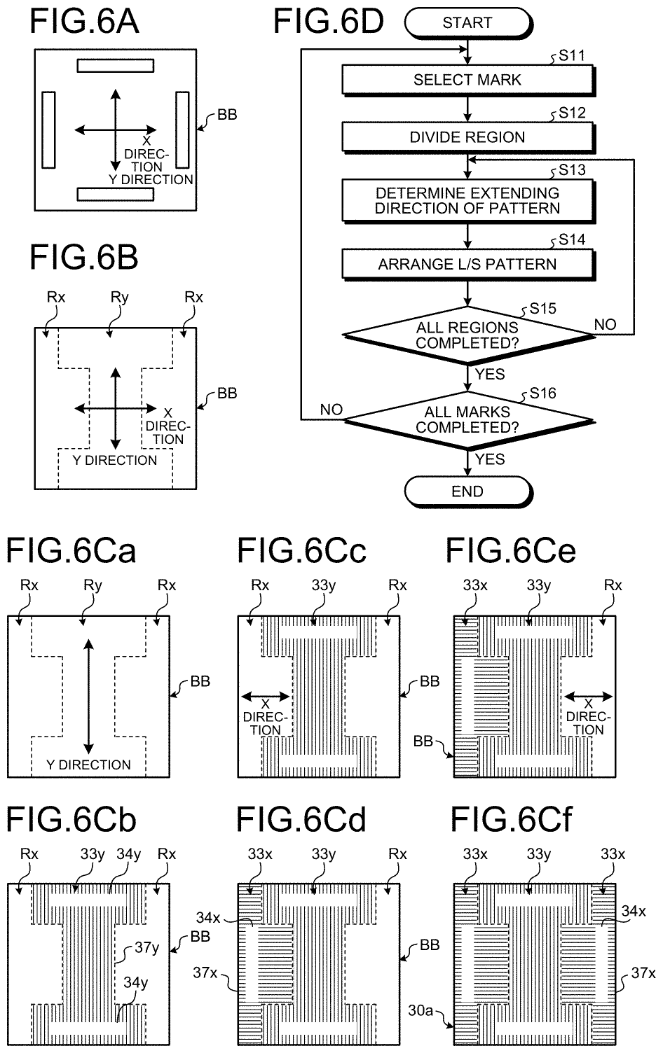

Next, an example of the method for manufacturing the template 10 of the first embodiment will be described with reference to FIGS. 6A to 8Bc.

The template 10 is manufactured by forming the transfer patterns 15p, the marks 30t, and the like on the unprocessed template substrate 14 (see FIG. 4) made of a transparent material such as crystal or glass, for example.

To form the transfer patterns 15p and the marks 30t, a multiple patterning process, which will be described later, may be used. The multiple patterning process can form minute patterns exceeding a resolution limit for the case of forming patterns by writing or exposure. As an example, L/S patterns of 14 nm pitch, for example, can be formed by the multiple patterning process.

On the other hand, it may be difficult for the multiple patterning process to form patterns other than L/S patterns having a constant pitch. Thus, it is also required to form the marks 30t by using the L/S patterns 37x and 37y as in the example of FIGS. 5A to 5C described above, for example.

The method for manufacturing the template 10 described below assumes the use of the multiple patterning process, for example.

FIGS. 6A to 6D are diagrams illustrating an example procedure of a method for designing the mark 30a provided to the template 10 according to the first embodiment. FIGS. 6A to 6Cf illustrate how the mark 30a is designed, and FIG. 6D is a flow chart of designing the mark 30a.

Note that, although it is assumed that the mark 30a described above is designed in the example of FIGS. 6A to 6D, other marks such as the mark 30b can be designed similarly.

As illustrated in FIG. 6D, the design of a mark of a plurality of types of marks that can be arranged on the template 10 is selected (step S11). In the example of FIG. 6A, a bar in bar mark BB is selected.

Next, the region occupied by the mark BB is divided into a region in which an X mark is arranged and a region in which a Y mark is arranged (step S12). In the example of FIG. 6B, the region occupied by the mark BB is divided into two regions Rx and one region Ry. The regions Rx are regions in which the X mark is arranged, and are arranged on both sides of the mark BB in the X direction, for example. The region Ry is a region in which the Y mark is arranged, and is sandwiched in the X direction and arranged at a central portion of the mark BB in the X direction, for example.

Next, the extending direction of the L/S pattern in any of the two regions Rx and one region Ry is determined (step S13). At this time, the extending direction of the L/S pattern is determined so as not to be orthogonal to the measurement directions of the X mark and the Y mark.

That is, it is determined such that, as seen from either one side of the measurement direction of the X mark extending the left-right direction on the page, the extending direction of the L/S pattern forms an angle less than 90° with the measurement direction and, as seen from the other side, the extending direction of the L/S pattern forms an angle greater than 90° with the measurement direction.

It is also determined such that, as seen from either one side of the measurement direction of the Y mark extending the up-down direction on the page, the extending direction of the L/S pattern forms an angle less than 90° with the measurement direction and, as seen from the other side, the extending direction of the L/S pattern forms an angle greater than 90° with the measurement direction.

In the example of FIG. 6Ca, the extending direction of the L/S pattern in the region Ry is determined to be the Y direction parallel to the measurement direction of the Y mark.

Next, the L/S pattern is arranged in the region Ry for which the extending direction of the L/S pattern is determined (step S14). In the example of FIG. 6Cb, an L/S pattern 37y extending in the Y direction is arranged in the region Ry. At this time, the arrangement positions of the pair of bar patterns 34y, in which the L/S pattern 37y is not arranged, are also determined.

Next, it is determined whether the processes of steps S13 and S14 described above are finished for all of the divided regions Rx and Ry in the mark BB and the design of all of the regions Rx and Ry is completed (step S15). If the design of any of the regions Rx and Ry is not completed (step S15: No), the processes of steps S13 and S14 are repeated.

In the example of FIG. 6Cc, for one of the two regions Rx for which the design has not been completed, the extending direction of the L/S pattern is determined to be the X direction parallel to the measurement direction of the X mark. As illustrated in FIG. 6Cd, the L/S pattern 37x extending in the X direction is arranged in the region Rx, including one bar pattern 34x in which the L/S pattern 37x is not arranged.

In the example of FIG. 6Ce, for the other of the two regions Rx for which the design has not been completed, the extending direction of the L/S pattern is determined to be the X direction parallel to the measurement direction of the X mark. As illustrated in FIG. 6Cf, the L/S pattern 37x extending in the X direction is arranged in the region Rx, including one bar pattern 34x in which the L/S pattern 37x is not arranged.

When the design of all of the regions Rx and Ry is thus completed (step S15: Yes), it is determined whether the processes of steps Sll to S15 described above are finished for all of the marks to be arranged on the template 10 and the design of all of the marks is completed (step S16).

If the design of any of the marks is not completed (step S16: No), the processes of steps S11 to S15 are repeated. If the design of all of the marks is completed (step S16: Yes), the process ends.

Thus, the design of the mark 30a of the first embodiment is completed.

Next, the transfer patterns 15p are formed on the unprocessed template substrate 14 by using the multiple patterning process, for example. In addition, the marks 30t are formed based on the design created as described above by similarly using the multiple patterning process.

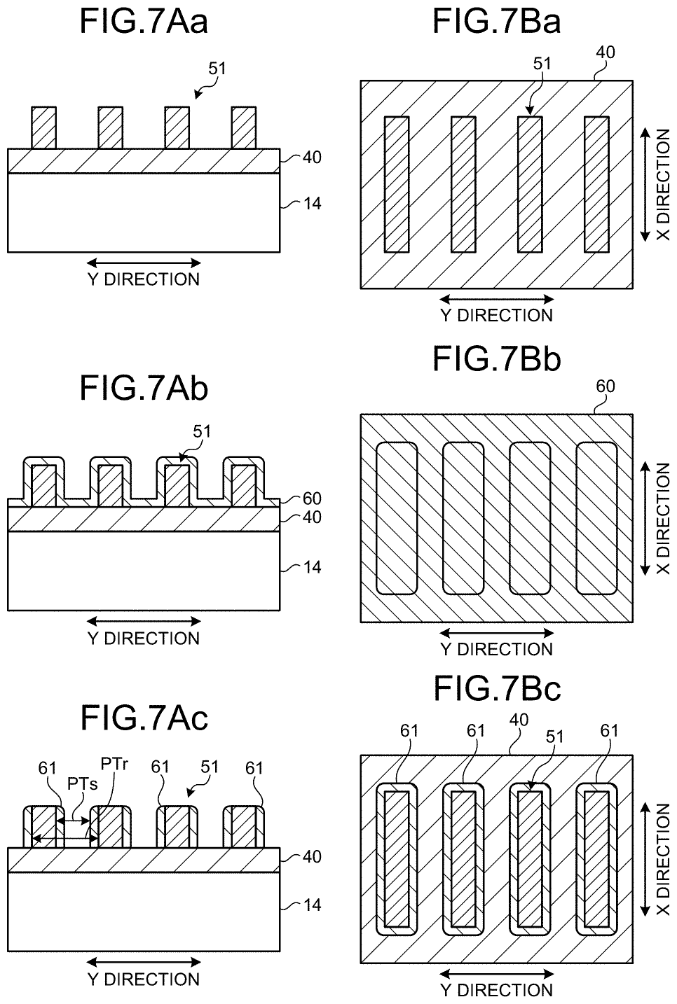

FIGS. 7Aa to 8Bc are diagrams illustrating an example procedure for forming the mark 30a provided to the template 10 according to the first embodiment. FIGS. 7Aa to 7Ac and 8Aa to Ac are sectional views of the template 10 along the Y direction in the manufacturing process. FIGS. 7Ba to 7Bc and 8Ba to Bc are plan views of the template 10 in the manufacturing process.

Note that FIGS. 7Aa to 8Bc illustrate the method for forming the L/S pattern 37x included in the X mark 33x of the mark 30a and extending in a direction along the X direction. The L/S pattern 37y included in the Y mark 33y of the mark 30a and extending in a direction along the Y direction is formed in parallel with the processes of FIGS. 7Aa to 8Bc. In addition, L/S patterns included in the transfer patterns 15p of the template 10, for example, and extending in various directions, for example, are formed in parallel with the processes of FIGS. 7Aa to 8Bc.

Other marks such as the mark 30b can also be formed similarly by the processes of FIGS. 7Aa to 8Bc.

As illustrated in FIGS. 7Aa and 7Ba, a mask film 40 such as a chromium film is formed on the surface of the unprocessed template substrate 14 made of a transparent material such as crystal or glass. A resist pattern 51 is formed on the mask film 40.

The resist pattern 51 has an L/S pattern extending in a direction along the X direction. The L/S pattern is formed by exposure using photolithography techniques, writing using electron beams, or the like, for example. The pitch of the L/S pattern is narrowed to the resolution limit of exposure or writing, for example, and is substantially constant between lines and between spaces. In addition, the pitch of the lines and the pitch of the spaces are substantially equal.

As illustrated in FIGS. 7Ab and 7Bb, a side wall film 60 is formed covering the resist pattern 51 and the mask film 40 exposed from the resist pattern 51. The side wall film 60 is, for example, a silicon oxide film, a silicon nitride film, a silicon oxynitride film, an amorphous silicon film, a polysilicon film, or the like.

As illustrated in FIGS. 7Ac and 7Bc, the side wall film 60 is etched back to expose the upper surface of the resist pattern 51 and the upper surface of the mask film 40 not covered by the resist pattern 51. In this manner, a side wall film pattern 61 covering the side walls of the resist pattern 51 is formed.

The side wall film pattern 61 covers the side walls of the resist pattern 51 opposing in the Y direction and the side walls of the resist pattern 51 at both X-direction end portions, and extends in a direction along the X direction with a predetermined pitch in the Y direction except for both X-direction end portions of the resist pattern 51. Here, the pitch PTs, of the side wall film pattern 61 is substantially half the initial pitch PTr, of the resist pattern 51.

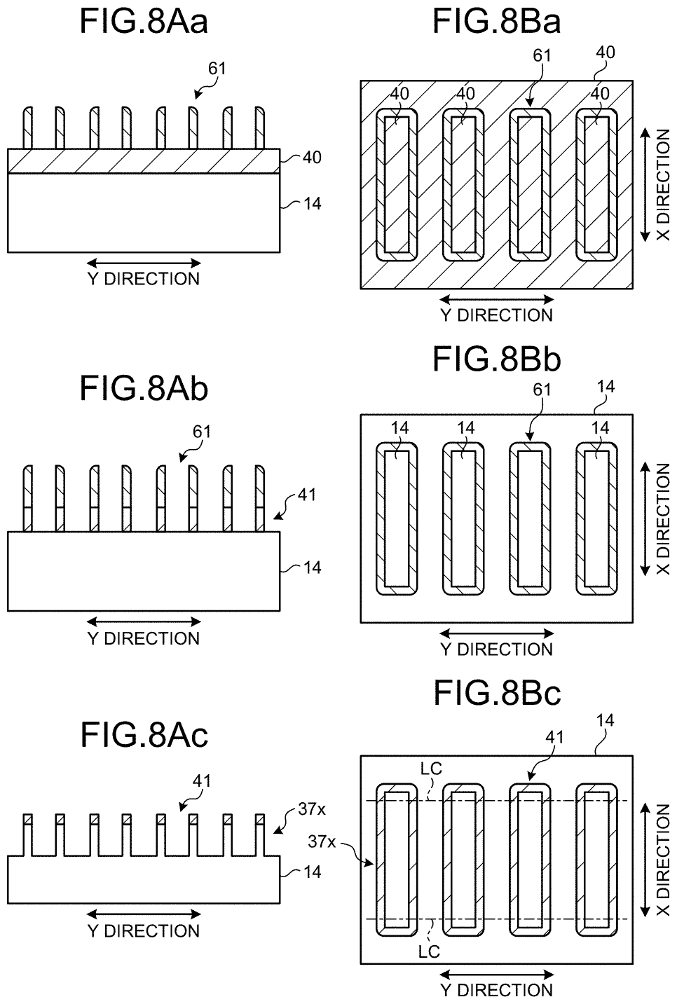

As illustrated in FIGS. 8Aa and 8Ba, the resist pattern 51 is removed by asking using oxygen plasma, a wet process using a remover, or the like. In this manner, a frame-shaped side wall film pattern 61 having a predetermined pitch in the Y direction and connected at both X-direction end portions is left on the mask film 40.

As illustrated in FIGS. 8Ab and 8Bb, the mask film 40 is processed by using the side wall film pattern 61 as a mask. In this manner, a frame-shaped mask pattern 41 having a pitch similar to the side wall film pattern 61 in the Y direction and connected at both X-direction end portions is formed on the template substrate 14.

As illustrated in FIGS. 8Ac and 8Bc, the template substrate 14 exposed from the mask pattern 41 is removed to a predetermined depth. In this manner, a frame-shaped L/S pattern 37x having a pitch similar to the mask pattern 41 in the Y direction and connected at both X-direction end portions is formed. As a result of this process, the side wall film pattern 61 on the mask pattern 41 is substantially lost, for example.

Thereafter, the mask pattern 41 on the L/S pattern 37x is removed, and both X-direction end portions of the L/S pattern 37x, that is, portions of the L/S pattern 37x outside cutting lines LC in the X direction are removed. In this manner, an L/S pattern 37x in which individual lines are separated is formed. The process of separating individual lines by removing both X-direction end portions of the L/S pattern 37x in this manner is also referred to as a loop cut process.

Thus, the L/S pattern 37x constituting the X mark 33x of the mark 30a of the first embodiment is formed.

The process of forming the L/S pattern 37x or the like having a pitch that is approximately half the pitch of the resist pattern 51 by using the resist pattern 51 or the like having a predetermined pitch as described above is referred to as a multiple patterning process or the like.

Note that, in the multiple patterning process, the materials of the side wall film 60, which will become the side wall film pattern 61, and the resist pattern 51, which serves as a core material for forming the side wall film pattern 61, are not limited to the above-described example, and materials suitable for the above-described process can be used in combination as appropriate.

In addition, in forming the L/S pattern 37x, the bar pattern 34x in which the L/S pattern 37x is not arranged can be formed by not forming the above-described resist pattern 51 in a partial region.

In addition, unlike the transfer patterns 15p, which will subsequently become part of the device portion of the semiconductor device, for example, the L/S pattern 37x constituting the X mark 33x of the mark 30a has no influence on the functionalities of the semiconductor device such as electrical operation. Therefore, the loop cut process may not be performed on the L/S pattern 37x. Similarly, the loop cut process can be omitted for the L/S pattern 37y constituting the Y mark 33y of the mark 30a.

Therefore, lines included in the L/S pattern 37x constituting the X mark 33x described above may be connected, at X-direction end portions of the X mark 33x, to respective adjacent lines on one of both sides in the Y direction.

Similarly, lines included in the L/S pattern 37y constituting the Y mark 33y described above may be connected, at Y-direction end portions of the Y mark 33y, to respective adjacent lines on one of both sides in the Y direction.

### COMPARATIVE EXAMPLE

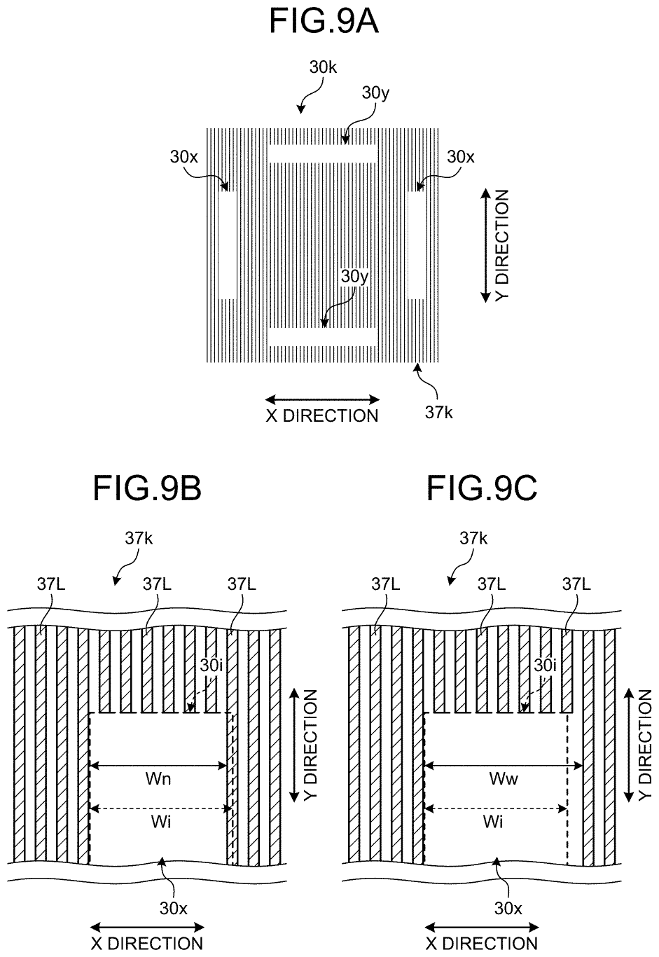

Next, a mark 30k of a comparative example will be described with reference to FIGS. 9A to 9C. FIGS. 9A to 9C are plan views of the mark 30k provided to a template according to the comparative example.

As illustrated in FIG. 9A, the mark 30k of the comparative example is entirely composed of an L/S pattern 37k extending in the Y direction, for example. The L/S pattern 37k includes a pair of bar patterns 30x extending in the Y direction at positions distanced in the X direction and serving as an X mark and a pair of bar patterns 30y extending in the X direction at positions distanced in the Y direction and serving as a Y mark.

FIGS. 9B and 9C illustrate some examples of arrangement of the L/S pattern 37k constituting the mark 30k of the comparative example in the vicinity of a bar pattern 30x. Assuming that the L/S pattern 37k of the comparative example is also formed by the multiple patterning process, the X-direction width of a designed arrangement region 30i of the bar pattern 30x may not be an integer multiple of the pitch of the L/S pattern 37k, as illustrated in FIGS. 9B and 9C.

Thus, if it is attempted to provide the bar pattern 30x, in which lines 37L of the L/S pattern 37k are not arranged, in agreement with the X-direction width Wi, of the arrangement region 30i, six lines 37L are not arranged in a region corresponding to the bar pattern 30x as illustrated in FIG. 9B or seven lines 37L are not arranged in the region as illustrated in FIG. 9C.

However, in the example of FIG. 9B, one line 37L enters inside the arrangement region 30i, and the X-direction width Wn, of the actual bar pattern 30x formed by the L/S pattern 37k is narrower than the designed width Wi. In addition, in the example of FIG. 9C, the X-direction width Ww, of the actual bar pattern 30x formed by the L/S pattern 37k is wider than the designed width Wi.

The marks 30a and 30b of the first embodiment include the X marks 33x and 35x in which the L/S pattern 37x extends in a direction along the X direction and the Y marks 33y and 35y in which the L/S pattern 37y extends in a direction along the Y direction.

In this manner, the width of the pairs of bar patterns 34x and 36x in the measurement direction can be adjusted by the length of lines included in the L/S pattern 37x in the direction along the X direction, instead of the number of the lines. In addition, the width of the pairs of bar patterns 34y and 36y in the measurement direction can be adjusted by the length of lines included in the L/S pattern 37y in the direction along the Y direction, instead of the number of the lines.

By setting the extending directions of the L/S patterns 37x and 37y to be not orthogonal to the respective measurement directions of the X marks 33x and 35x or the Y marks 33y and 35y in this manner, it is possible to precisely control the widths of the pairs of bar patterns 34x and 36x and the pairs of bar patterns 34y and 36y in the measurement direction. This can improve the precision of the alignment and overlay misalignment measurement using the marks 30a and 30b.

Note that, in the first embodiment described above, the bar patterns 34x, 36x, 34y, and 36y are formed by arranging the L/S patterns 37x and 37y around the bar patterns 34x and 36x of the X marks 33x and 35x and the bar patterns 34y and 36y of the Y marks 33y and 35y and not arranging the L/S patterns 37x and 37y in the bar patterns 34x, 36x, 34y, and 36y.

However, these marks may also be formed by inverting the region in which the L/S patterns 37x and 37y are arranged and the region in which they are not arranged. That is, by arranging the L/S patterns 37x and 37y in the bar patterns of the respective marks and not arranging them in other regions, it is possible to form marks in which the arrangement regions of the L/S patterns 37x and 37y are inverted as compared to the marks 30a and 30b described above.

(First Variation)

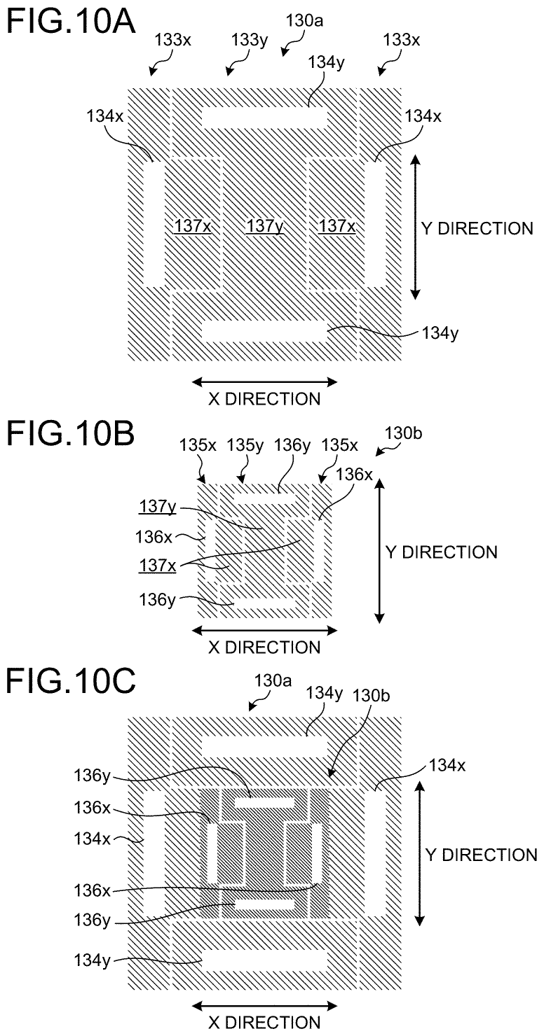

Next, marks 130a and 130b of a first variation of the first embodiment will be described with reference to FIGS. 10A to 10C. The marks 130a and 130b of the first variation are different than in the first embodiment described above in including L/S patterns 137x and 137y diagonally intersecting the respective measurement directions of X marks 133x and 135x and Y marks 133y and 135y.

FIGS. 10A to 10C are plan views illustrating an example configuration of the marks 130a and 130b provided to a template according to the first variation of the first embodiment. The marks 130a and 130b of the first variation have designs similar to those of the marks 30a and 30b of the first embodiment described above.

Therefore, either of the marks 130a and 130b of the first variation may be arranged on the template of the first variation, and both are usable as either alignment marks or overlay marks.

In addition, the marks 130a and 130b illustrated in FIGS. 10A to 10C are shown as seen from above the wafer of the first variation. That is, in FIGS. 10A to 10C, the left-right direction on the page in the X direction is consistent for both of the marks 130a and 130b.

Note that a mark arranged on the wafer out of the marks 130a and 130b of the first variation may not necessarily be formed by an L/S pattern.

As illustrated in FIG. 10A, the mark 130a of the first variation includes an X mark 133x and a Y mark 133y.

The X mark 133x as a first mark includes bar patterns 134x as a pair of first patterns distanced in the X direction and extending in a direction along the Y direction, and is composed of an L/S pattern 137x having a substantially constant pitch. The L/S pattern 137x extends in a direction diagonally intersecting the X direction, which is the measurement direction of the X mark 133x. The angle of the L/S pattern 137x to the X direction may be substantially 45°, for example.

The Y mark 133y as a second mark includes bar patterns 134y as a pair of second patterns distanced in the Y direction and extending in a direction along the X direction, and is composed of an L/S pattern 137y having a substantially constant pitch. The L/S pattern 137y extends in a direction diagonally intersecting the Y direction, which is the measurement direction of the Y mark 133y. The angle of the L/S pattern 137y to the Y direction may be substantially 45°, for example.

In addition, the pitches of the lines and spaces in the L/S pattern 137x in the Y direction and the pitches of the lines and spaces in the L/S pattern 137y in the X direction are substantially equal respectively.

In addition, the diagonal directions of the L/S patterns 137x and 137y may be the same. That is, as in the example of FIG. 10A, both of the L/S patterns 137x and 137y may extend from the upper left portion of the page toward the lower right portion of the page, for example.

Further, both of the L/S patterns 137x and 137y may extend in the same direction. That is, as in the example of FIG. 10A, both of the angles of the L/S patterns 137x and 137y to the X direction and the Y direction may be substantially 45°, for example.

As illustrated in FIG. 10B, the mark 130b of the first variation includes an X mark 135x and a Y mark 135y.

The X mark 135x as a first mark includes a pair of bar patterns 136x distanced in the X direction and extending in a direction along the Y direction, and is composed of the L/S pattern 137x, for example, similar to the X mark 133x of FIG. 10A.

The Y mark 135y as a second mark includes a pair of bar patterns 136y distanced in the Y direction and extending in a direction along the X direction, and is composed of the L/S pattern 137y, for example, similar to the Y mark 133y of FIG. 10A.

In addition, similar to the mark 130a of FIG. 10A, the diagonal directions of the L/S patterns 137x and 137y of the mark 130b may be the same. Further, both of the L/S patterns 137x and 137y may extend in the same direction.

FIG. 10C illustrates how the marks 130a and 130b are overlaid. The alignment and overlay misalignment measurement using the marks 130a and 130b are performed in a manner similar to the alignment and overlay misalignment measurement using the marks 30a and 30b of the first embodiment described above.

That is, in alignment in the X direction, the X-direction center position between the pair of bar patterns 134x of the X mark 133x of the mark 130a and the X-direction center position between the pair of bar patterns 136x of the X mark 135x of the mark 130b are matched.

In addition, in alignment in the Y direction, the Y-direction center position between the pair of bar patterns 134y of the Y mark 133y of the mark 130a and the Y-direction center position between the pair of bar patterns 136y of the Y mark 135y of the mark 130b are matched.

Note that, in the above-described alignment, one of the marks 130a and 130b is arranged on the template of the first variation and the other one is arranged on a predetermined film on the wafer.

As a result of the above-described alignment, the X- and Y-direction relative positions between the transfer patterns of the template of the first variation and the structures on the wafer are adjusted to prescribed positions.

In addition, in overlay misalignment measurement in the X direction, the distance between the X-direction center position between the pair of bar patterns 134x of the X mark 133x of the mark 130a and the X-direction center position between the pair of bar patterns 136x of the X mark 135x of the mark 130b is measured.

In addition, in overlay misalignment measurement in the Y direction, the distance between the Y-direction center position between the pair of bar patterns 134y of the Y mark 133y of the mark 130a and the Y-direction center position between the pair of bar patterns 136y of the Y mark 135y of the mark 130b is measured.

Note that, in the above-described overlay misalignment measurement, one of the marks 130a and 130b is transferred from the template of the first variation to the resist on the wafer and the other one is arranged on a predetermined film on the wafer.

As a result of the above-described overlay misalignment measurement, the amounts of overlay misalignment between the patterns transferred from the template of the first variation to the resist on the wafer and the structures on the wafer in the X direction and the Y direction are obtained.

According to the marks 130a and 130b of the first variation, the L/S pattern 137x of the X marks 133x and 135x extends in a direction diagonally intersecting the X direction and the L/S pattern 137y of the Y marks 133y and 135y extends in a direction diagonally intersecting the Y direction.

As above, in the marks 130a and 130b of the first variation as well, the extending directions of the L/S patterns 137x and 137y are not orthogonal to the measurement directions of the respective marks. Thus, it is possible to precisely control the widths of the bar patterns 134x, 134y, 136x, and 136y and to improve the precision of the alignment and overlay misalignment measurement.

According to the marks 130a and 130b of the first variation, both of the L/S patterns 137x and 137y extend in the same direction. This allows the L/S patterns 137x and 137y to have a common configuration and makes it easier to design and form the X marks 133x and 135x and the Y marks 133y and 135y.

Note that, for the marks 130a and 130b of the first variation as well, the marks may be formed by inverting the region in which the L/S patterns 137x and 137y are arranged and the region in which the L/S patterns 137x and 137y are not arranged as compared to the example of FIG. 10 described above.

In addition, for the marks 130a and 130b of the first variation as well, both extending-direction end portions of the L/S patterns 137x and 137y constituting the respective marks 130a and 130b may be connected in a loop shape.

(Second Variation)

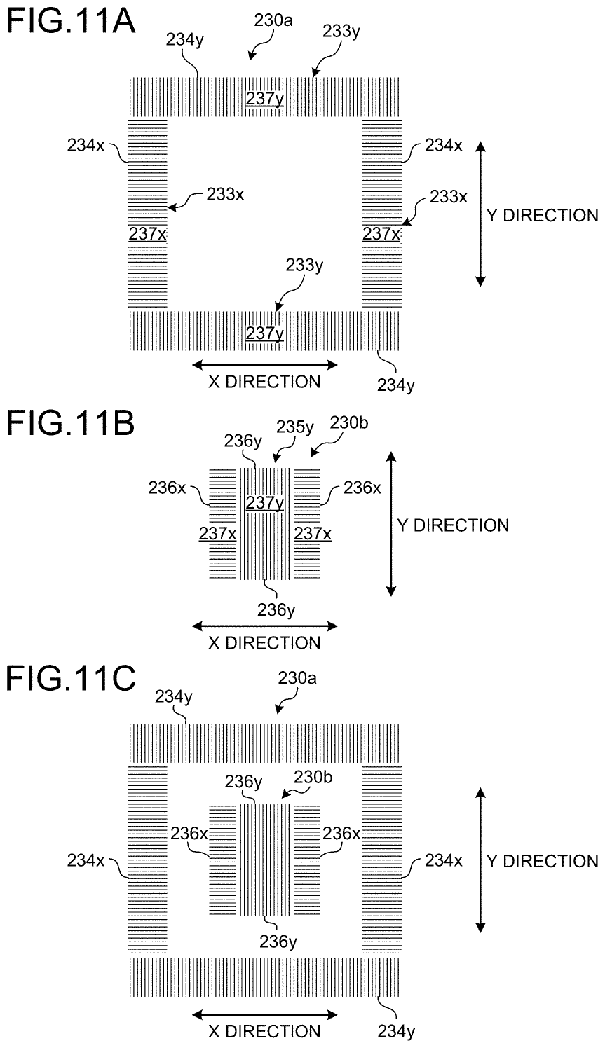

Next, marks 230a and 230b of a second variation of the first embodiment will be described with reference to FIGS. 11A to 11C. The marks 230a and 230b of the second variation are different than in the first embodiment described above in being a box in box mark.

FIGS. 11A to 11C are plan views illustrating an example configuration of the marks 230a and 230b provided to a template according to the second variation of the first embodiment. The marks 230a and 230b of the second variation are a pair of marks having designs complementary to each other, one arranged on the template of the second variation and the other arranged on the wafer.

Either of the marks 230a and 230b of the second variation may be arranged on the template of the second variation, and both are usable as either alignment marks or overlay marks. The pair of marks 230a and 230b is referred to as a box in box mark, for example, due to its design.

In addition, both of the marks 230a and 230b illustrated in FIGS. 11A to 11C are shown as seen from above the wafer of the second variation. That is, in FIGS. 11A to 11C, the left-right direction on the page in the X direction is consistent for both of the marks 230a and 230b.

Note that a mark arranged on the wafer out of the marks 230a and 230b of the second variation may not necessarily be formed by an L/S pattern.

As illustrated in FIG. 11A, the mark 230a of the second variation includes an X mark 233x and a Y mark 233y.

The X mark 233x as a first mark includes bar patterns 234x as a pair of first patterns distanced in the X direction and extending in a direction along the Y direction. The pair of bar patterns 234x are composed of an L/S pattern 237x having a substantially constant pitch. The L/S pattern 237x extends in a direction along the X direction, which is the measurement direction of the X mark 233x, for example.

The Y mark 233y as a second mark includes bar patterns 234y as a pair of second patterns distanced in the Y direction and extending in a direction along the X direction. The pair of bar patterns 234y are composed of an L/S pattern 237y having a substantially constant pitch. The L/S pattern 237y extends in a direction along the Y direction, which is the measurement direction of the Y mark 233y, for example.

In addition, the pitches of the lines and spaces in the L/S pattern 237x in the Y direction and the pitches of the lines and spaces in the L/S pattern 237y in the X direction are substantially equal respectively.

The mark 230a of the second variation has a frame-shaped design in which the pair of bar patterns 234x constituting the X mark 233x and the pair of bar patterns 234y constituting the Y mark 233y are combined, for example.

As illustrated in FIG. 11B, the mark 230b of the second variation includes an X mark 235x and a Y mark 235y.

The X mark 235x as a first mark includes a pair of bar patterns 236x distanced in the X direction and extending in a direction along the Y direction. The pair of bar patterns 236x are composed of the L/S pattern 237x, for example, similar to the bar patterns 234x of FIG. 11A.

The Y mark 235y as a second mark is sandwiched by the X mark 235x on both sides in the X direction and extends in a direction along the Y direction. In addition, the Y mark 235y includes a pair of bar patterns 236y distanced in the Y direction, extending in a direction along the X direction, and constituting sides of the Y mark 235y at both Y-direction end portions. The pair of bar patterns 236y are composed of the L/S pattern 237y, for example, similar to the bar patterns 234y of FIG. 11A.

The mark 230b of the second variation has a rectangular design in which the X mark 235x and the Y mark 233y are combined, for example.

FIG. 11C illustrates how the marks 230a and 230b are overlaid. The alignment and overlay misalignment measurement using the marks 230a and 230b are performed in a manner similar to the alignment and overlay misalignment measurement using the marks 30a and 30b of the first embodiment described above.

That is, in alignment in the X direction, the X-direction center position between the pair of bar patterns 234x of the X mark 233x of the mark 230a and the X-direction center position between the pair of bar patterns 236x of the X mark 235x of the mark 230b are matched.

In addition, in alignment in the Y direction, the Y-direction center position between the pair of bar patterns 234y of the Y mark 233y of the mark 230a and the Y-direction center position between the pair of bar patterns 236y of the Y mark 235y of the mark 230b are matched.

Note that, in the above-described alignment, one of the marks 230a and 230b is arranged on the template of the second variation and the other one is arranged on a predetermined film on the wafer.

As a result of the above-described alignment, the X- and Y-direction relative positions between the transfer patterns of the template of the second variation and the structures on the wafer are adjusted to prescribed positions.

In addition, in overlay misalignment measurement in the X direction, the distance between the X-direction center position between the pair of bar patterns 234x of the X mark 233x of the mark 230a and the X-direction center position between the pair of bar patterns 236x of the X mark 235x of the mark 230b is measured.

In addition, in overlay misalignment measurement in the Y direction, the distance between the Y-direction center position between the pair of bar patterns 234y of the Y mark 233y of the mark 230a and the Y-direction center position between the pair of bar patterns 236y of the Y mark 235y of the mark 230b is measured.

Note that, in the above-described overlay misalignment measurement, one of the marks 230a and 230b is transferred from the template of the second variation to the resist on the wafer and the other one is arranged on a predetermined film on the wafer.

As a result of the above-described overlay misalignment measurement, the amounts of overlay misalignment between the patterns transferred from the template of the second variation to the resist on the wafer and the structures on the wafer in the X direction and the Y direction are obtained.

The marks 230a and 230b of the second variation achieve effects similar to those of the marks 30a and 30b of the first embodiment described above.

Note that, for the marks 230a and 230b of the second variation as well, the marks may be formed by inverting the region in which the L/S patterns 237x and 237y are arranged and the region in which the L/S patterns 237x and 237y are not arranged as compared to the example of FIG. 11 described above.

In addition, in the marks 230a and 230b of the second variation as well, the L/S patterns constituting them may extend in directions diagonally intersecting the respective measurement directions. In addition, the diagonal directions of the L/S patterns of the X mark and the Y mark may be the same. Further, both of these L/S patterns may extend in the same direction.

In addition, for the marks 230a and 230b of the second variation as well, both extending-direction end portions of the L/S patterns constituting the respective marks 230a and 230b may be connected in a loop shape.

(Third Variation)

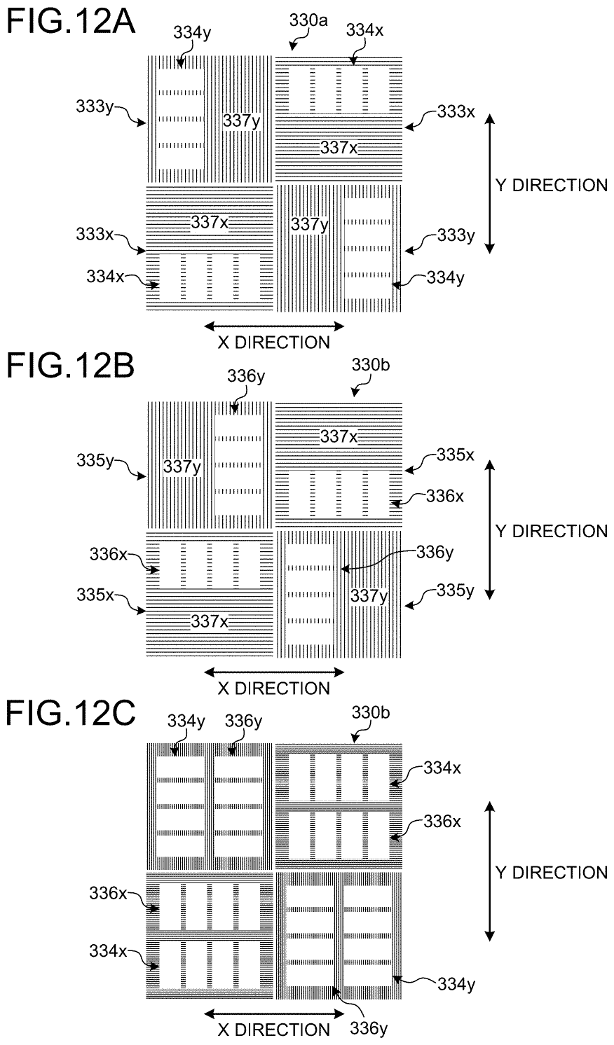

Next, marks 330a and 330b of a third variation of the first embodiment will be described with reference to FIGS. 12A to 12C. The marks 330a and 330b of the third variation are different than in the first embodiment described above in being an AIM mark.

FIGS. 12A to 12C are plan views illustrating an example configuration of the marks 330a and 330b provided to a template according to the third variation of the first embodiment. The marks 330a and 330b of the third variation are a pair of marks having designs complementary to each other, one arranged on the template of the third variation and the other arranged on the wafer.

Either of the marks 330a and 330b of the third variation may be arranged on the template of the third variation, and both are usable as either alignment marks or overlay marks. The pair of marks 330a and 330b are referred to as an advanced imaging metrology (AIM) mark, for example, due to their measurement technique using advanced imaging.

In addition, both of the marks 330a and 330b illustrated in FIGS. 12A to 12C are shown as seen from above the wafer of the third variation. That is, in FIGS. 12A to 12C, the left-right direction on the page in the X direction is consistent for both of the marks 330a and 330b.

Note that a mark arranged on the wafer out of the marks 330a and 330b of the third variation may not necessarily be formed by an L/S pattern.

As illustrated in FIG. 12A, the mark 330a of the third variation includes an X mark 333x and a Y mark 333y.

The X mark 333x as a first mark includes rectangular patterns 334x as a pair of first patterns arranged at a distance in the X direction, and is composed of an L/S pattern 337x having a substantially constant pitch. The L/S pattern 337x extends in a direction along the X direction, which is the measurement direction of the X mark 333x, for example.

In addition, the L/S pattern 337x is separated into two rectangular regions, each including one rectangular pattern 334x, and is arranged on a diagonal line of the mark 330a entirely formed with a generally rectangular shape.

The pair of rectangular patterns 334x are regions in which the L/S pattern 337x is not arranged in the rectangular region of the L/S pattern 337x and each include a plurality of rectangular patterns arrayed in the Y direction. In addition, the pair of rectangular patterns 334x are each included in a corresponding one of two L/S patterns 337x arranged on a diagonal line of the mark 330a and are arranged at positions distanced in the Y direction.

The Y mark 333y as a second mark includes rectangular patterns 334y as a pair of second patterns arranged at a distance in the Y direction, and is composed of an L/S pattern 337y having a substantially constant pitch. The L/S pattern 337y extends in a direction along the Y direction, which is the measurement direction of the Y mark 333y, for example.

The pitches of the lines and spaces in the L/S pattern 337x in the Y direction and the pitches of the lines and spaces in the L/S pattern 337y in the X direction are substantially equal respectively.

In addition, the L/S pattern 337y is separated into two rectangular regions, each including one rectangular pattern 334y, and is arranged on a diagonal line of the mark 330a entirely formed with a generally rectangular shape.

The pair of rectangular patterns 334y are regions in which the L/S pattern 337y is not arranged in the rectangular region of the L/S pattern 337y and each include a plurality of rectangular patterns arrayed in the X direction. In addition, the pair of rectangular patterns 334y are each included in a corresponding one of two L/S patterns 337y arranged on a diagonal line of the mark 330a and are arranged at positions distanced in the X direction.

The mark 330a of the third variation has a rectangular design in which two rectangular L/S patterns 337x arranged on a diagonal line to each other and constituting the X mark 333x and two rectangular L/S patterns 337y arranged on a diagonal line to each other and constituting the Y mark 333y are combined.

As illustrated in FIG. 12B, the mark 330b of the third variation includes an X mark 335x and a Y mark 335y.

The X mark 335x as a first mark includes rectangular patterns 336x as a pair of first patterns arranged at a distance in the X direction, and is composed of the L/S pattern 337x, for example, similar to the X mark 333x of FIG. 12A.

The L/S pattern 337x is separated into two rectangular regions, each including one rectangular pattern 336x, and is arranged on a diagonal line of the mark 330b entirely formed with a generally rectangular shape.

The pair of rectangular patterns 336x are regions in which the L/S pattern 337x is not arranged in the rectangular region of the L/S pattern 337x and each include a plurality of rectangular patterns arrayed in the Y direction. In addition, the pair of rectangular patterns 336x are each included in a corresponding one of two L/S patterns 337x arranged on a diagonal line of the mark 330b and are arranged at positions distanced in the Y direction.

The X-direction distance between the pair of rectangular patterns 336x is shorter than the X-direction distance between the pair of rectangular patterns 334x included in the X mark 333x of FIG. 12A.

The Y mark 335y as a second mark includes rectangular patterns 336y as a pair of second patterns arranged at a distance in the Y direction, and is composed of the L/S pattern 337y, for example, similar to the Y mark 333y of FIG. 12A.

The L/S pattern 337y is separated into two rectangular regions, each including one rectangular pattern 336y, and is arranged on a diagonal line of the mark 330b entirely formed with a generally rectangular shape.

The pair of rectangular patterns 336y are regions in which the L/S pattern 337y is not arranged in the rectangular region of the L/S pattern 337y and each include a plurality of rectangular patterns arrayed in the X direction. In addition, the pair of rectangular patterns 336y are each included in a corresponding one of two L/S patterns 337y arranged on a diagonal line of the mark 330b and are arranged at positions distanced in the X direction.

The Y-direction distance between the pair of rectangular patterns 336y is shorter than the Y-direction distance between the pair of rectangular patterns 334y included in the Y mark 333y of FIG. 12A.

The mark 330b of the third variation has a rectangular design in which the X mark 335x and the Y mark 335y are combined in a manner similar to the mark 330a of FIG. 12A.

FIG. 12C illustrates how the marks 330a and 330b are overlaid. The alignment and overlay misalignment measurement using the marks 330a and 330b are performed in a manner similar to the alignment and overlay misalignment measurement using the marks 30a and 30b of the first embodiment described above.

That is, in alignment in the X direction, the center position between the pair of rectangular patterns 334x of the X mark 333x of the mark 330a and the center position between the pair of rectangular patterns 336x of the X mark 335x of the mark 330b are matched in the X direction. At this time, a process of matching these center positions in the Y direction as well may be performed accessorily.

In addition, in alignment in the Y direction, the center position between the pair of rectangular patterns 334y of the Y mark 333y of the mark 330a and the center position between the pair of rectangular patterns 336y of the Y mark 335y of the mark 330b are matched in the Y direction. At this time, a process of matching these center positions in the X direction as well may be performed accessorily.

Note that, in the above-described alignment, one of the marks 330a and 330b is arranged on the template of the third variation and the other one is arranged on a predetermined film on the wafer.

As a result of the above-described alignment, the X- and Y-direction relative positions between the transfer patterns of the template of the third variation and the structures on the wafer are adjusted to prescribed positions.

In addition, in overlay misalignment measurement in the X direction, the X-direction distance between the center position between the pair of rectangular patterns 334x of the X mark 333x of the mark 330a and the center position between the pair of rectangular patterns 336x of the X mark 335x of the mark 330b is measured. At this time, the Y-direction distance between these center positions may also be measured as a reference value.

In addition, in overlay misalignment measurement in the Y direction, the Y-direction distance between the center position between the pair of rectangular patterns 334y of the Y mark 333y of the mark 330a and the center position between the pair of rectangular patterns 336y of the Y mark 335y of the mark 330b is measured. At this time, the X-direction distance between these center positions may also be measured as a reference value.

Note that, in the above-described overlay misalignment measurement, one of the marks 330a and 330b is transferred from the template of the third variation to the resist on the wafer and the other one is arranged on a predetermined film on the wafer.

As a result of the above-described overlay misalignment measurement, the amounts of overlay misalignment between the patterns transferred from the template of the third variation to the resist on the wafer and the structures on the wafer in the X direction and the Y direction are obtained.

Note that, in the example of FIG. 12C, the marks 330a and 330b are illustrated as being overlaid in an ideal state in which the misalignment amount is zero in both the X direction and the Y direction.

At this time, one of the pair of rectangular patterns 334x is adjacent in the X direction to one of the pair of rectangular patterns 336x in the region in which one of the X marks 333x and one of the X marks 335x are overlaid. In addition, the other of the pair of rectangular patterns 334x is adjacent in the X direction to the other of the pair of rectangular patterns 336x in the region in which the other of the X marks 333x and the other of the X marks 335x are overlaid.

In addition, at this time, one of the pair of rectangular patterns 334y is adjacent in the Y direction to one of the pair of rectangular patterns 336y in the region in which one of the Y marks 333y and one of the Y marks 335y are overlaid. In addition, the other of the pair of rectangular patterns 334y is adjacent in the Y direction to the other of the pair of rectangular patterns 336y in the region in which the other of the Y marks 333y and the other of the Y marks 335y are overlaid.

The marks 330a and 330b of the third variation achieve effects similar to those of the marks 30a and 30b of the first embodiment described above.

Note that, for the marks 330a and 330b of the third variation as well, the marks may be formed by inverting the region in which the L/S patterns 337x and 337y are arranged and the region in which the L/S patterns 337x and 337y are not arranged as compared to the example of FIGS. 12A to 12C described above.

In addition, in the marks 330a and 330b of the third variation as well, the L/S patterns constituting them may extend in directions diagonally intersecting the respective measurement directions. In addition, the diagonal directions of the L/S patterns of the X mark and the Y mark may be the same. Further, both of these L/S patterns may extend in the same direction.

In addition, for the marks 330a and 330b of the third variation as well, both extending-direction end portions of the L/S patterns constituting the respective marks 330a and 330b may be connected in a loop shape.

### Second Embodiment

A second embodiment will be described in detail below with reference to the drawings. Alignment marks of the second embodiment are different than in the first embodiment described above in being moire marks.

(Outlines of Moire Marks)

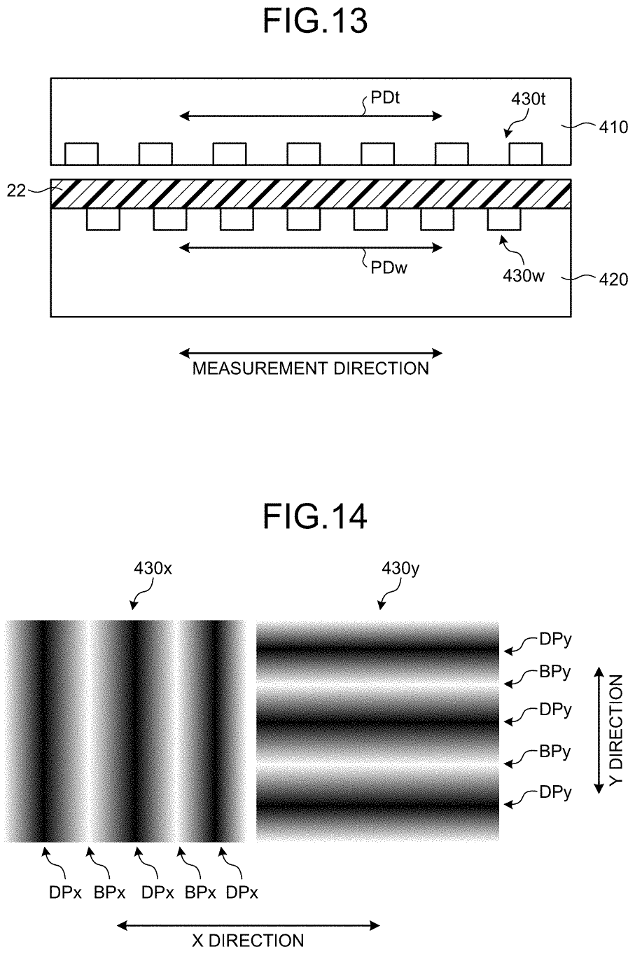

First, a schematic configuration and the functionality of moire marks 430t and 430w will be described with reference to FIGS. 13 and 14.

FIG. 13 is a sectional view along the measurement direction of the marks 430t and 430w respectively provided to a template 410 and a wafer 420 according to the second embodiment, illustrating a schematic configuration of the marks 430t and 430w.

While the imprint process may require a nano-order positional precision, there is a limit to simple alignment by means of an optical system with a wavelength of several hundreds of nm. Thus, the marks 430t and 430w of the second embodiment use a precise alignment technique using an enlargement effect resulting from a moire pattern.

More specifically, an interference pattern referred to as a moire pattern having a predetermined period can be generated by allowing the marks 430t and 430w of the template 410 and the wafer 420 to each have a periodic structure and their respective periodic intervals to be slightly different. Using such a moire pattern allows enlarged projection of misalignment, enabling precise alignment.

As illustrated in FIG. 13, the template 410 includes the mark 430t having a predetermined period PDt in the measurement direction. The wafer 420 includes the mark 430w having a predetermined period PDw in the measurement direction. The period PDt of the mark 430t and the mark 430w of the period PDw are different. When the marks 430t and 430w configured in this manner are overlaid, a moire pattern is observed.

The direction of periodicity of the moire pattern generated by the marks 430t and 430w is equal to the direction of periodicity of the patterns of the marks 430t and 430w, that is, equal to the measurement direction of the marks 430t and 430w. The misalignment amount between the template 410 and the wafer 420 in the measurement direction can be detected by observing the moire pattern along the direction of periodicity of the moire pattern.

More specifically, the moire pattern is observed as a microscopic image by observing the marks 430t and 430w after overlaying the marks 430t and 430w of the template 410 and the wafer 420 and applying oblique incident light in a dark field system.

FIG. 14 is a schematic diagram illustrating an example of moire patterns generated by the marks 430t and 430w according to the second embodiment.

As illustrated in FIG. 14, when the marks 430t and 430w are overlaid, a region 430x in which respective X marks included in the marks 430t and 430w are overlaid and a region 430y in which respective Y marks included in the marks 430t and 430w are overlaid are formed.

In the region 430x in which the X marks of the marks 430t and 430w are overlaid, high-order diffracted light occurs at portions in which the respective patterns included in the marks 430t and 430w are overlaid, and the light enters the field of view to form bright portions BPx. On the other hand, at portions in which the respective patterns of the marks 430t and 430w are not overlaid, diffracted light is significantly reduced, and it becomes harder for the diffracted light to enter the field of view, forming dark portions DPx.

The marks 430t and 430w have the respective different periods PDt and PDw. Thus, as the coordinate of one of the marks 430t and 430w in the X direction, which is the measurement direction of the X mark, changes in proportion to the average periodic interval of the marks 430t and 430w, the periodic pattern of the moire pattern formed by the bright portions BPx and dark portions DPx described above moves in the X direction.

At this time, the phase of the moire pattern changes at a period larger than the actual amount of displacement in the relative position between the marks 430t and 430w. That is, the amount of displacement of the marks 430t and 430w in the X direction is detected in a scale enlarged by the moire pattern having periodicity in the X direction.

Similarly, in the region 430y in which the Y marks of the marks 430t and 430w are overlaid as well, portions in which the respective patterns included in the marks 430t and 430w are overlaid form bright portions BPy, and portions in which the patterns are not overlaid form dark portions DPy.

In addition, as the coordinate of one of the marks 430t and 430w in the Y direction, which is the measurement direction of the Y mark, changes in proportion to the average periodic interval of the marks 430t and 430w, the periodic pattern of the moire pattern formed by the bright portions BPy and dark portions DPy described above moves in the Y direction.

At this time, for the Y mark as well as in the case of the X mark of the marks 430t and 430w, the amount of displacement of the marks 430t and 430w in the Y direction is detected in a scale enlarged by the moire pattern having periodicity in the Y direction.

Such an effect of enlarging the amount of displacement by the moire pattern allows the actual amount of displacement of the marks 430t and 430w to be captured in an enlarged scale, enabling precise alignment in the X direction and the Y direction by means of the marks 430t and 430w. That is, with the marks 430t and 430w, a high enlargement ratio, a high contrast, and a high S/N ratio are obtained in the alignment between the template 410 and the wafer 420.

As described above, moire marks such as the marks 430t and 430w are used for alignment between the template 410 and the wafer 420 during the imprint process and allow precise alignment.

(Example Configuration of Marks)

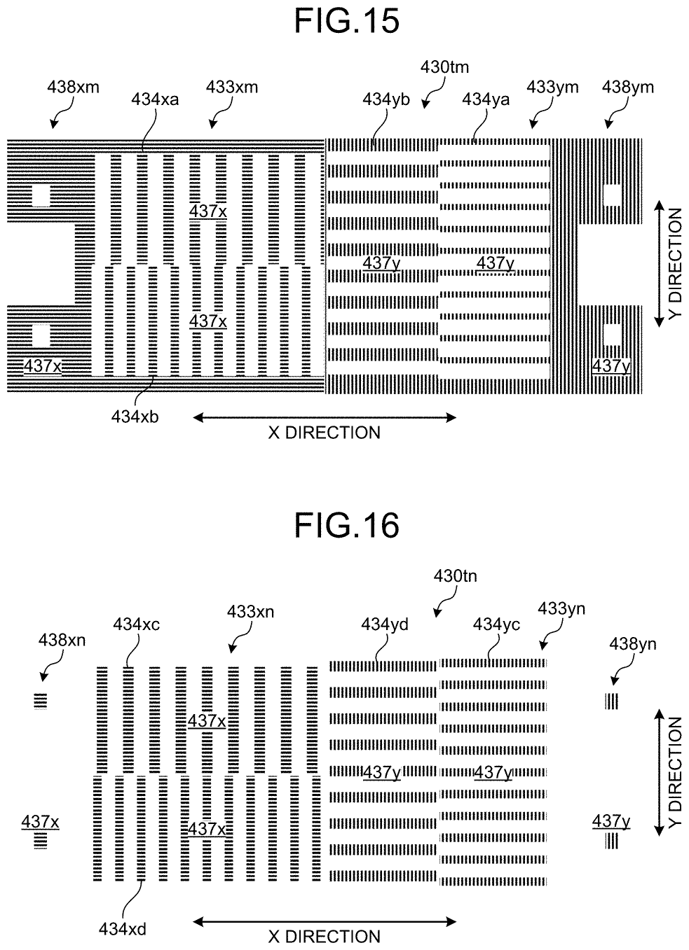

Next, example configurations of marks 430tm, 430tn, 430wp, and 430wq respectively provided to the template 410 and the wafer 420 of the second embodiment will be described with reference to FIGS. 15 to 18.

FIG. 15 is a plan view illustrating an example configuration of a mark 430tm provided to the template 410 according to the second embodiment. As illustrated in FIG. 15, the mark 430tm includes an X mark 433xm, a Y mark 433ym, and rough inspection marks 438xm and 438ym.

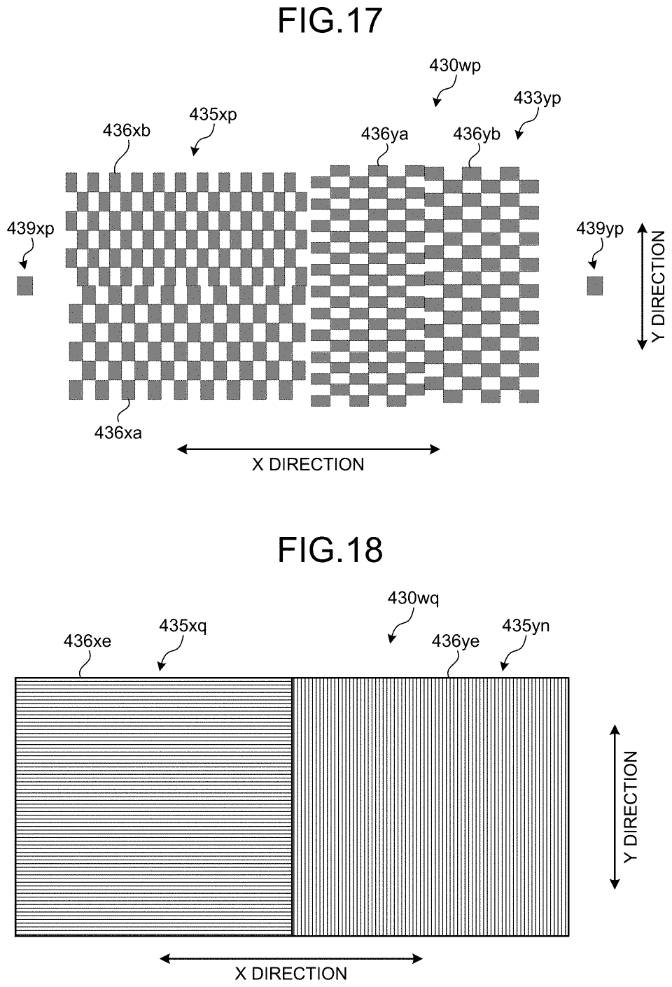

Note that the mark 430tm illustrated in FIG. 15 is shown as seen from above the wafer 420. That is, the left-right direction on the page in the X direction in FIG. 15 coincides with the left-right direction on the page for the marks 430wp and 430wq on the wafer 420, which will be described later in FIGS. 17 and 18.

The X mark 433xm as a first mark is configured as a moire mark that generates a moire pattern having a period in the X direction, and is an alignment mark used for alignment in the X direction between the transfer patterns of the template 410 and the structures on the wafer 420, for example.

The X mark 433xm includes periodic patterns 434xa and 434xb having periods different from each other in the X direction. That is, the pitches of the periodic patterns 434xa and 434xb are different from each other, and both can be micron-order, for example.

As an example, the designed half pitches of the periodic patterns 434xa and 434xb can be 1.0 μm and 1.05 μm, respectively, for example. The actual pitches of the periodic patterns 434xa and 434xb may include manufacturing errors.

The periodic patterns 434x a and 434x b as first periodic patterns are both composed of an L/S pattern 437x having a substantially constant pitch and extending in a direction along the X direction. That is, the periodic patterns 434xa and 434xb are formed by arraying regions in which the L/S pattern 437x is arranged and regions in which the L/S pattern 437x is not arranged at respective different periods in the X direction.

The Y mark 433ym as a second mark is configured as a moire mark that generates a moire pattern having a period in the Y direction, and is an alignment mark used for alignment in the Y direction between the transfer patterns of the template 410 and the structures on the wafer 420, for example.

The Y mark 433ym includes periodic patterns 434ya and 434yb having periods different from each other in the Y direction. That is, the pitches of the periodic patterns 434ya and 434yb are different from each other, and both can be micron-order, for example.

As an example, the designed half pitches of the periodic patterns 434ya and 434yb can be 1.0 μm and 1.06 μm, respectively, for example. However, the pitches of the periodic patterns 434ya and 434yb may be different from the pitches of the periodic patterns 434xa and 434xb of the X mark 433xm. The actual pitches of the periodic patterns 434ya and 434yb may include manufacturing errors.

The periodic patterns 434ya and 434yb as second periodic patterns are both composed of an L/S pattern 437y having a substantially constant pitch and extending in a direction along the Y direction. That is, the periodic patterns 434ya and 434yb are formed by arraying regions in which the L/S pattern 437y is arranged and regions in which the L/S pattern 437y is not arranged at respective different periods in the Y direction.

In addition, the pitches of the lines and spaces in the L/S pattern 437x in the Y direction and the pitches of the lines and spaces in the L/S pattern 437y in the X direction are substantially equal respectively.

The rough inspection marks 438xm and 438ym are used for roughly aligning the positions of the template 410 and the wafer 420 in the X direction and the Y direction before precise alignment using the X mark 433xm and the Y mark 433ym. The rough inspection marks 438xm and 438ym may also be formed by using L/S patterns, for example.

In the example of FIG. 15, the rough inspection mark 438xm is composed of the L/S pattern 437x, and the rough inspection mark 438ym is composed of the L/S pattern 437y. However, the alignment precision required for the rough inspection marks 438xm and 438ym is not as high as that for the X mark 433xm and the Y mark 433ym.

FIG. 16 is a plan view illustrating an example configuration of another mark 430tn provided to the template 410 according to the second embodiment. As illustrated in FIG. 16, the mark 430tn includes an X mark 433xn, a Y mark 433yn, and rough inspection marks 438xn and 438yn.

Note that the mark 430tn illustrated in FIG. 16 is shown as seen from above the wafer 420. That is, the left-right direction on the page in the X direction in FIG. 16 coincides with the left-right direction on the page for the marks 430wp and 430wq on the wafer 420, which will be described later in FIGS. 17 and 18.

The X mark 433xn as a first mark is configured as a moire mark that generates a moire pattern having a period in the X direction, and is an alignment mark used for alignment in the X direction between the transfer patterns of the template 410 and the structures on the wafer 420, for example.

The X mark 433xn includes periodic patterns 434xc and 434xd having periods different from each other in the X direction. That is, the pitches of the periodic patterns 434xc and 434xd are different from each other, and both can be micron-order, for example.

As an example, the designed half pitches of the periodic patterns 434xc and 434xd can be 1.0 μm and 1.06 μm, respectively, for example. The actual pitches of the periodic patterns 434xc and 434xd may include manufacturing errors.

The periodic patterns 434xc and 434xd as first periodic patterns are composed of the L/S pattern 437x, for example, similar to the periodic patterns 434xa and 434xb included in the X mark 433xm of FIG. 15.

The Y mark 433yn as a second mark is configured as a moire mark that generates a moire pattern having a period in the Y direction, and is an alignment mark used for alignment in the Y direction between the transfer patterns of the template 410 and the structures on the wafer 420, for example.

The Y mark 433yn includes periodic patterns 434yc and 434yd having periods different from each other in the Y direction. That is, the pitches of the periodic patterns 434yc and 434yd are different from each other, and both can be micron-order, for example.

As an example, the designed half pitches of the periodic patterns 434yc and 434yd can be 1.0 μm and 1.06 μm, respectively, for example. However, the pitches of the periodic patterns 434yc and 434yd may be different from the pitches of the periodic patterns 434xc and 434xd of the X mark 433xn. The actual pitches of the periodic patterns 434yc and 434yd may include manufacturing errors.

The periodic patterns 434yc and 434yd as second periodic patterns are composed of the L/S pattern 437y, for example, similar to the periodic patterns 434ya and 434yb included in the Y mark 433ym of FIG. 15.

The rough inspection marks 438xn and 438yn are used for rough alignment in the X direction and the Y direction, and the rough inspection marks 438xn and 438yn may also be formed by using L/S patterns, for example. In the example of FIG. 16, the rough inspection mark 438xn is composed of the L/S pattern 437x, and the rough inspection mark 438yn is composed of the L/S pattern 437y.

Note that, in the marks 430tm and 430tn as well, the L/S patterns constituting them may extend in directions diagonally intersecting the respective measurement directions. In addition, the diagonal directions of the L/S patterns of the X mark and the Y mark may be the same. Further, both of these L/S patterns may extend in the same direction.

In addition, for the marks 430tm and 430tn as well, both extending-direction end portions of the L/S patterns constituting the respective marks 430tm and 430tn may be connected in a loop shape.

FIG. 17 is a plan view illustrating an example configuration of a mark 430wp provided to the wafer 420 according to the second embodiment. As illustrated in FIG. 17, the mark 430wp includes an X mark 435xp, a Y mark 435yp, and rough inspection marks 439xp and 43yp.

The X mark 435xp is configured as a moire mark that generates a moire pattern having a period in the X direction by being overlaid on the X mark 433xm or 433xn of the template 410 illustrated in FIG. 15 or 16, and is an alignment mark used for alignment in the X direction between the transfer patterns of the template 410 and the structures on the wafer 420, for example.

The X mark 435xp includes periodic patterns 436xa and 436xb having periods different from each other in the X direction. That is, the pitches of the periodic patterns 436xa and 436xb are different from each other, and both can be micron-order, for example.

When used in combination with the X mark 433xm of the template 410 illustrated in FIG. 15, the periodic pattern 436xa overlaid on the periodic pattern 434xb of the X mark 433xm is configured to have a period different from that of the periodic pattern 434xb. The periodic pattern 436xb overlaid on the periodic pattern 434xa of the X mark 433xm is configured to have a period different from that of the periodic pattern 434xa.

Note that the period of the periodic pattern 436xa may be equal to the period of the periodic pattern 434xb of the X mark 433xm of the template 410, and the period of the periodic pattern 436xb may be equal to the period of the periodic pattern 434xa of the X mark 433xm of the template 410.

When used in combination with the X mark 433xn of the template 410 illustrated in FIG. 16, the periodic pattern 436xa overlaid on the periodic pattern 434xd of the X mark 433xn is configured to have a period different from that of the periodic pattern 434xd. The periodic pattern 436xb overlaid on the periodic pattern 434xc of the X mark 433xn is configured to have a period different from that of the periodic pattern 434xc.

Note that the period of the periodic pattern 436xa may be equal to the period of the periodic pattern 434xd of the X mark 433xn of the template 410, and the period of the periodic pattern 436xb may be equal to the period of the periodic pattern 434xc of the X mark 433xn of the template 410.

The Y mark 435yp is configured as a moire mark that generates a moire pattern having a period in the Y direction by being overlaid on the Y mark 433ym or 433yn of the template 410 illustrated in FIG. 15 or 16, and is an alignment mark used for alignment in the Y direction between the transfer patterns of the template 410 and the structures on the wafer 420, for example.

The Y mark 435yp includes periodic patterns 436ya and 436yb having periods different from each other in the Y direction. That is, the pitches of the periodic patterns 436ya and 436yb are different from each other, and both can be micron-order, for example.

When used in combination with the Y mark 433ym of the template 410 illustrated in FIG. 15, the periodic pattern 436ya overlaid on the periodic pattern 434yb of the Y mark 433ym is configured to have a period different from that of the periodic pattern 434yb. The periodic pattern 436yb overlaid on the periodic pattern 434ya of the Y mark 433ym is configured to have a period different from that of the periodic pattern 434ya.

Note that the period of the periodic pattern 436ya may be equal to the period of the periodic pattern 434yb of the Y mark 433ym of the template 410, and the period of the periodic pattern 436yb may be equal to the period of the periodic pattern 434ya of the Y mark 433ym of the template 410.

Alternatively, when used in combination with the Y mark 433yn of the template 410 illustrated in FIG. 16, the periodic pattern 436ya overlaid on the periodic pattern 434yd of the Y mark 433yn is configured to have a period different from that of the periodic pattern 434yd. The periodic pattern 436yb overlaid on the periodic pattern 434yc of the Y mark 433yn is configured to have a period different from that of the periodic pattern 434yc.

Note that the period of the periodic pattern 436ya may be equal to the period of the periodic pattern 434yd of the Y mark 433yn of the template 410, and the period of the periodic pattern 436yb may be equal to the period of the periodic pattern 434yc of the Y mark 433yn of the template 410.

As a result of configuring the mark 430wp of the wafer 420 as described above, a moire pattern is generated by overlaying either the mark 430tm or 430tn of the template 410 and the mark 430wp of the wafer 420, enabling precise alignment between the template 410 and the wafer 420.

That is, in alignment in the X direction, either the X mark 433xm or 433xn of the template 410 and the X mark 435xp of the wafer 420 are overlaid to generate a moire pattern having a predetermined period in the X direction. In addition, the X-direction relative position between either the X mark 433xm or 433xn and the X mark 435xp is adjusted so as to decrease the amount of deviation of the periodic pattern of the moire pattern in the X direction. In this manner, the X-direction relative position between the transfer patterns of the template 410 and the structures on the wafer 420 is adjusted to a prescribed position.

In addition, in alignment in the Y direction, either the Y mark 433ym or 433yn of the template 410 and the Y mark 435yp of the wafer 420 are overlaid to generate a moire pattern having a predetermined period in the Y direction. In addition, the Y-direction relative position between either the Y mark 433ym or 433yn and the Y mark 435yp is adjusted so as to decrease the amount of deviation of the periodic pattern of the moire pattern in the Y direction. In this manner, the Y-direction relative position between the transfer patterns of the template 410 and the structures on the wafer 420 is adjusted to a prescribed position.

Thus, in any of the marks 430tm, 430tn, and 430wp, the X marks 433xm, 433xn, and 435xp are used for measurement of the misalignment amount in the X direction, and the Y marks 433ym, 433yn, and 435yp are used for measurement of the misalignment amount in the Y direction. Then, alignment in the X direction and the Y direction is performed based on the measured amounts of misalignment.

The rough inspection marks 439xp and 439yp are used for roughly aligning the positions of the template 410 and the wafer 420 in the X direction and the Y direction before precise alignment using the X mark 435xp and the Y mark 435yp.

The rough inspection mark 439xp is overlaid on either the rough inspection mark 438xm or 438xn of the template 410, and is adjusted to a position at which the rough inspection mark 439xp and either the rough inspection mark 438xm or 438xn are aligned in the Y direction. In this manner, the X-direction relative position between the transfer patterns of the template 410 and the structures on the wafer 420 is roughly adjusted.

In addition, the rough inspection mark 439xp is adjusted to be arranged at the Y-direction center position of either the rough inspection mark 438xm or 438xn aligned in the Y direction. In this manner, the Y-direction relative position between the transfer patterns of the template 410 and the structures on the wafer 420 is roughly adjusted.

The rough inspection mark 439yp is overlaid on either the rough inspection mark 438ym or 438yn of the template 410, and X- and Y-direction alignment between the rough inspection mark 439yp and either the rough inspection mark 438ym or 438yn is performed as in the case of the rough inspection mark 439xp.

FIG. 18 is a plan view illustrating an example configuration of another mark 430wq provided to the wafer 420 according to the second embodiment. As illustrated in FIG. 18, the mark 430wq includes an X mark 435xq and a Y mark 435yq.

The X mark 435xq is configured as a moire mark that generates a moire pattern having a period in the X direction by being overlaid on the X mark 433xm or 433xn of the template 410 illustrated in FIG. 15 or 16, and is an alignment mark used for alignment in the X direction between the transfer patterns of the template 410 and the structures on the wafer 420, for example.

The X mark 435xq includes a periodic pattern 436xe having a predetermined period in the X direction. The pitch of the periodic pattern 436xe can be micron-order, for example.

When used in combination with the X mark 433xm of the template 410 illustrated in FIG. 15, the periodic pattern 436xe is overlaid on both of the periodic patterns 434xa and 434xb of the X mark 433xm. Thus, the periodic pattern 436xe is configured to have a period different from either of the periodic patterns 434xa and 434xb.

Alternatively, when used in combination with the X mark 433xn of the template 410 illustrated in FIG. 16, the periodic pattern 436xe is overlaid on both of the periodic patterns 434xc and 434xd of the X mark 433xn. Thus, the periodic pattern 436xe is configured to have a period different from either of the periodic patterns 434xc and 434xd.

The Y mark 435yq is configured as a moire mark that generates a moire pattern having a period in the Y direction by being overlaid on the Y mark 433ym or 433yn of the template 410 illustrated in FIG. 15 or 16, and is an alignment mark used for alignment in the Y direction between the transfer patterns of the template 410 and the structures on the wafer 420, for example.

The Y mark 435yq includes a periodic pattern 436ye having a predetermined period in the Y direction. The pitch of the periodic pattern 436ye can be micron-order, for example.

When used in combination with the Y mark 433ym of the template 410 illustrated in FIG. 15, the periodic pattern 436ye is overlaid on both of the periodic patterns 434ya and 434yb of the Y mark 433ym. Thus, the periodic pattern 436ye is configured to have a period different from either of the periodic patterns 434xa and 434yb.

Alternatively, when used in combination with the Y mark 433yn of the template 410 illustrated in FIG. 16, the periodic pattern 436ye is overlaid on both of the periodic patterns 434yc and 434yd of the Y mark 433yn. Thus, the periodic pattern 436ye is configured to have a period different from either of the periodic patterns 434yc and 434yd.

As a result of configuring the mark 430wq of the wafer 420 as described above, a moire pattern is generated by overlaying either the mark 430tm or 430tn of the template 410 and the mark 430wq of the wafer 420, enabling precise alignment between the template 410 and the wafer 420.

That is, in alignment in the X direction, the X-direction relative position between either the X mark 433xm or 433xn and the X mark 435xq is adjusted so as to decrease the amount of X-direction deviation of the periodic pattern of the moire pattern generated by overlaying either the X mark 433xm or 433xn of the template 410 and the X mark 435xq of the wafer 420.

In alignment in the Y direction, the Y-direction relative position between either the Y mark 433ym or 433yn and the Y mark 435yq is adjusted so as to decrease the amount of Y-direction deviation of the periodic pattern of the moire pattern generated by overlaying either the Y mark 433ym or 433yn of the template 410 and the Y mark 435yp of the wafer 420.

In this manner, the X- and Y-direction relative positions between the transfer patterns of the template 410 and the structures on the wafer 420 are adjusted to prescribed positions.

The mark 430tm or 430tn of the second embodiment includes the X mark 433xm or 433xn that includes the periodic patterns 434xa and 434xb or periodic patterns 434xc and 434xd having periods in the X direction and in which the extending direction of the L/S pattern 437x is not orthogonal to the X direction and the Y mark 433ym or 433yn that includes the periodic patterns 434ya and 434yb or periodic patterns 434yc and 434yd having periods in the Y direction and in which the extending direction of the L/S pattern 437y is not orthogonal to the X direction.

With a moire mark such as the mark 430tm or 430tn, high-precision alignment is enabled by precisely controlling the periods of the periodic patterns in the respective measurement directions.

According to the configuration of the second embodiment described above, the periods of the periodic patterns 434xa to 434xd can be adjusted by the length of lines included in the L/S pattern 437x in the direction along the X direction, instead of the number of the lines. In addition, the periods of the periodic patterns 434ya to 434yd can be adjusted by the length of lines included in the L/S pattern 437y in the direction along the Y direction, instead of the number of the lines.

In this manner, it is possible to precisely control the periods of the periodic patterns 434xa to 434xd and 434ya to 434yd in the respective measurement directions and to further improve the precision of alignment.

### Other Embodiments

In the first and second embodiments and the first to third variations and the like described above, a mark arranged on the template 10, 410, or the like used for the imprint process is composed of an L/S pattern not orthogonal to the measurement direction of the mark. However, such configuration can also be applied to a mark other than that of the template. For example, the above-described configuration may be applied to a mark arranged on a photomask used for exposure using photolithography techniques, or the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A mark arranged on a substrate and including a line-and-space pattern having a substantially constant pitch on the substrate, the mark comprising:
a first mark in which the line-and-space pattern extends in a direction at an angle that is less than 90° or greater than 90° with respect to the first direction, the first mark including a pair of first patterns arranged at a distance in a first direction along the substrate or a first periodic pattern having a period in the first direction; and
a second mark in which the line-and-space pattern extends in a direction at an angle that is less than 90° or greater than 90° with respect to the second direction, the second mark including a pair of second patterns provided in correspondence with the pair of first patterns and arranged at a distance in a second direction along the substrate and intersecting the first direction or a second periodic pattern provided in correspondence with the first periodic pattern and having a period in the second direction.

2. The mark according to claim 1, wherein
the line-and-space pattern of the first mark extends in a direction along the first direction, and
the line-and-space pattern of the second mark extends in a direction along the second direction.

3. The mark according to claim 1, wherein
the line-and-space pattern of the first mark extends in a direction diagonally intersecting the first direction, and
the line-and-space pattern of the second mark extends in a direction diagonally intersecting the second direction.

4. The mark according to claim 1, wherein
a plurality of lines included in the line-and-space pattern included in the first mark is connected, at end portions in the first direction, to respective adjacent lines on one of both sides in the second direction, and
a plurality of lines included in the line-and-space pattern included in the second mark is connected, at end portions in the second direction, to respective adjacent lines on one of both sides in the first direction.

5. The mark according to claim 1, wherein
the mark is a box in box, bar in bar, or AIM mark, the mark including:
the first mark including the pair of first patterns; and
the second mark including the pair of second patterns.

6. The mark according to claim 1, wherein
the substrate further includes a transfer pattern to be transferred to a film to be processed which is provided over a wafer, and
the mark is an overlay mark for measuring an overlay misalignment between the transfer pattern that has been transferred and a structure included in at least one of the film to be processed and an underlying film of the film to be processed.

7. The mark according to claim 1, wherein
the mark is a moire mark, the mark including:
the first mark including the first periodic pattern; and
the second mark including the second periodic pattern.

8. The mark according to claim 1, wherein
the substrate further includes a transfer pattern to be transferred to a film to be processed which is provided over a wafer, and
the mark is an alignment mark used for alignment between the transfer pattern of the substrate and a structure included in at least one of the film to be processed and an underlying film of the film to be processed.

9. A semiconductor device manufacturing method including a misalignment amount measurement for measuring a misalignment amount of a transfer pattern with respect to a structure included in at least one of a film to be processed and an underlying film of the film to be processed which are provided on a wafer by using the mark according to claim 1, the transfer pattern being provided on the substrate and being transferred to the film to be processed, the semiconductor device manufacturing method comprising:
measuring a misalignment amount of the transfer pattern with respect to the structure in the first direction by using the first mark; and
measuring a misalignment amount of the transfer pattern with respect to the structure in the second direction by using the second mark.

10. The semiconductor device manufacturing method according to claim 9, wherein
the measurement using the first mark includes
identifying an overlay misalignment amount of the transfer pattern that has been transferred with respect to the structure in the first direction based on the misalignment amount in the first direction, and
the measurement using the second mark includes
identifying an overlay misalignment amount of the transfer pattern that has been transferred with respect to the structure in the second direction based on the misalignment amount in the second direction.

11. The semiconductor device manufacturing method according to claim 9, wherein
the measurement using the first mark includes
aligning a position of the transfer pattern provided on the substrate with respect to the structure in the first direction by using the first mark based on the misalignment amount in the first direction, and
the measurement using the second mark includes
aligning a position of the transfer pattern provided on the substrate with respect to the structure in the second direction by using the second mark based on the misalignment amount in the second direction.

12. A template comprising:
a substrate; and
a mark including a line-and-space pattern having a substantially constant pitch on the substrate, wherein
the mark includes:
a first mark in which the line-and-space pattern extends in a direction at an angle that is less than 90° or greater than 90° with respect to the first direction, the first mark including a pair of first patterns arranged at a distance in a first direction along the substrate or a first periodic pattern having a period in the first direction; and
a second mark in which the line-and-space pattern extends in a direction at an angle that is less than 90° or greater than 90° with respect to the second direction, the second mark including a pair of second patterns provided in correspondence with the pair of first patterns and arranged at a distance in a second direction along the substrate and intersecting the first direction or a second periodic pattern provided in correspondence with the first periodic pattern and having a period in the second direction.

13. The template according to claim 12, wherein
the line-and-space pattern of the first mark extends in a direction along the first direction, and
the line-and-space pattern of the second mark extends in a direction along the second direction.

14. The template according to claim 12, wherein
the line-and-space pattern of the first mark extends in a direction diagonally intersecting the first direction, and
the line-and-space pattern of the second mark extends in a direction diagonally intersecting the second direction.

15. The template according to claim 12, wherein
a plurality of lines included in the line-and-space pattern included in the first mark is connected, at end portions in the first direction, to respective adjacent lines on one of both sides in the second direction, and
a plurality of lines included in the line-and-space pattern included in the second mark is connected, at end portions in the second direction, to respective adjacent lines on one of both sides in the first direction.

16. The template according to claim 12, wherein
the mark is a box in box, bar in bar, or AIM mark, the mark including:
the first mark including the pair of first patterns; and
the second mark including the pair of second patterns.

17. The template according to claim 12, further comprising:
a transfer pattern on the substrate to be transferred to a film to be processed which is provided over a wafer, wherein
the mark is an overlay mark for measuring an overlay misalignment between the transfer pattern that has been transferred and a structure included in at least one of the film to be processed and an underlying film of the film to be processed.

18. The template according to claim 12, further comprising:
a transfer pattern on the substrate to be transferred to a film to be processed which is provided over a wafer, wherein
the mark is a moire mark, the mark including:
the first mark including the first periodic pattern; and
the second mark including the second periodic pattern.

19. The template according to claim 12, wherein
the mark is an alignment mark used for alignment between the transfer pattern of the template and a structure included in at least one of the film to be processed and an underlying film of the film to be processed.
